(19) United States
(12) Patent Application Publication
(10) Pub. No.: US 2013/0240870 A1
(43) Pub. Date: Sep. 19, 2013

(54) VAPOR DEPOSITION DEVICE, VAPOR DEPOSITION METHOD AND ORGANIC EL DISPLAY DEVICE

(71) Applicants: Shinichi Kawato, Osaka (JP); Satoshi Inoue, Osaka (JP); Tohru Sonoda, Osaka (JP)

(72) Inventors: Shinichi Kawato, Osaka (JP); Satoshi Inoue, Osaka (JP); Tohru Sonoda, Osaka (JP)

(73) Assignee: SHARP KABUSHIKI KAISHA, Osaka-shi, Osaka (JP)

(21) Appl. No.: 13/989,757

(22) PCT Filed: Dec. 13, 2011
(86) PCT No.: PCT/JP2011/078749

§ 371 Date: May 24, 2013

(30) Foreign Application Priority Data
Dec. 21, 2010 (JP) 2010-284940

(51) Int. Cl. H01L 51/56; H01L 51/50

(52) U.S. Cl. CPC H01L 51/56; H01L 51/50
USPC 257/40; 257/88; 118/720; 438/46

(57) ABSTRACT

A vapor deposition source (60), a limiting plate unit (80), and a vapor deposition mask (70) are disposed in this order. The limiting plate unit includes a plurality of limiting plates (81) disposed along a first direction. The side surfaces of the limiting plates defining a limiting space (82) in the first direction are configured such that a portion having a dimension in the first direction of the limiting space between the limiting plates neighboring in the first direction wider than a narrowest portion (81n) having a narrowest dimension in the first direction of the limiting space is formed on at least the vapor deposition source side with respect to the narrowest portion. Accordingly, a coating film whose edge blur is suppressed can be formed at a desired position on a large-sized substrate.

### TECHNICAL FIELD

The present invention relates to a vapor deposition device and a vapor deposition method for forming a coating film having a predetermined pattern on a substrate. The present invention also relates to an organic EL (Electro Luminescence) display device including a light emitting layer formed by vapor deposition.

### BACKGROUND ART

In recent years, flat panel displays are used in various commodity products and fields, and thus flat panel displays are required to have a large size, high image quality and low power consumption.

Under the circumstances, organic EL display devices, which include an organic EL element that utilizes electro luminescence of an organic material, are attracting great attention as all-solid state flat panel displays that are excellent as having capability of low voltage operation, quick responsivity and light emission.

Active matrix type organic EL display devices, for example, are provided with a thin film-like organic EL element on a substrate having a TFT (thin film transistor). In the organic EL element, organic EL layers including a light emitting layer are laminated between a pair of electrodes. The TFT is connected to one of the pair of electrodes. Then, voltage is applied across the pair of electrodes so as to cause the light emitting layer to emit light, whereby an image is displayed.

In a full-color organic EL display device, generally, organic EL elements including light emitting layers of respective colors of red (R), green (G) and blue (B) are formed and arranged on a substrate as sub-pixels. By causing these organic EL elements to selectively emit light at the desired brightness by using the TFT, a color image is displayed.

In order to manufacture an organic EL display device, it is necessary to form a light emitting layer made of organic light emitting materials that emit respective colors in a predetermined pattern for each organic EL element.

Known methods for forming light emitting layers in a predetermined pattern are vacuum vapor deposition method, inkjet method and laser transfer method. For example, the vacuum vapor deposition method is often used for low molecular organic EL display devices (OLEDs).

In the vacuum vapor deposition method, a mask (also called a “shadow mask”) having a predetermined pattern of openings is used. The deposition surface of a substrate having the mask closely fixed thereto is disposed so as to oppose a vapor deposition source. Then, vapor deposition particles (film forming material) from the vapor deposition source are deposited onto the deposition surface through the openings of the mask, whereby a predetermined pattern of a thin film is formed. Vapor deposition is performed for each color of the light emitting layer, which is referred to as “vapor deposition by color”.

For example, Patent Documents 1 and 2 disclose a method for performing vapor deposition by color in which light emitting layers for respective colors are formed by sequentially moving a mask with respect to a substrate. With such a method, a mask having a size equal to that of a substrate is used, and the mask is fixed so as to cover the deposition surface of the substrate at the time of vapor deposition.

With conventional methods for performing vapor deposition by color as described above, as the substrate becomes larger, the mask needs to be large accordingly. However, when the mask is made large, a gap is likely to appear between the substrate and the mask by the mask being bent by its own weight or being extended. In addition, the size of the gap varies depending on the position of the deposition surface of the substrate. For this reason, it is difficult to perform highly accurate patterning, and it is therefore difficult to achieve high definition due to the occurrence of positional offset between the mask and the substrate during vapor deposition and the occurrence of color mixing.

Also, when the mask is made large, the mask as well as a frame or the like for holding the mask need to be gigantic, which increases the weight and makes handling thereof difficult. As a result, there is a possibility that productivity and safety might be compromised. Also, the vapor deposition device and devices that are used together therewith need to be made gigantic and complex as well, which makes device designing difficult and increases the installation cost.

For the reasons described above, the conventional methods for vapor deposition by color that are described in Patent Documents 1 and 2 are difficult to adapt to large-sized substrates, and it is difficult to perform vapor deposition by color on large-sized substrates such as those having a size exceeding 60 inches on a mass manufacturing level.

Patent Document 3 describes a vapor deposition method for causing vapor deposition particles discharged from a vapor deposition source to adhere to a substrate after causing the vapor deposition particles to pass through a mask opening of a vapor deposition mask while relatively moving the vapor deposition source and the vapor deposition mask with respect to the substrate. With this vapor deposition method, even in the case of large-sized substrates, it is not necessary to increase the size of the vapor deposition mask in accordance with the size of the substrates.

Patent Document 4 describes that a columnar-shaped or rectangle columnar-shaped vapor deposition beam direction adjustment plate having vapor deposition beam-pass-through holes formed therein whose diameter is approximately 0.1 mm to 1 mm is disposed between a vapor deposition source and a vapor deposition mask. By causing the vapor deposition particles discharged from the vapor deposition beam emission hole of the vapor deposition source to pass through the vapor deposition beam-pass-through holes formed in the vapor deposition beam direction adjustment plate, the directivity of vapor deposition beam can be increased.

### CITATION LIST

### Patent Document

Patent Document 1: JP H8-227276A
Patent Document 2: JP 2000-188179A
Patent Document 3: JP 2004-349101A
Patent Document 4: JP 2004-103269A

### DISCLOSURE OF INVENTION

### Problem to be Solved by the Invention

According to the vapor deposition method described in Patent Document 3, a vapor deposition mask smaller than the substrate can be used, and therefore vapor deposition can be easily performed on large-sized substrates.

However, because it is necessary to relatively move the vapor deposition mask with respect to the substrate, the substrate and the vapor deposition mask need to be spaced apart from each other. With Patent Document 3, vapor deposition particles that fly from various directions may enter the mask openings of the vapor deposition mask, and therefore the width of the coating film formed on the substrate is longer than the width of the mask opening, resulting blur at the edge of the coating film.

Patent Document 4 describes that the directivity of the vapor deposition beam entering the vapor deposition mask is improved by the vapor deposition beam direction adjustment plate.

However, in the actual vapor deposition step, the vapor deposition particles adhere to the inner circumferential surfaces of the vapor deposition beam-pass-through holes formed in the vapor deposition beam direction adjustment plate. Because the vapor deposition beam direction adjustment plate is disposed so as to oppose the vapor deposition source, it is heated by radiant heat from the vapor deposition source. Therefore, the vapor deposition particles that has adhered to the inner circumferential surfaces of the vapor deposition beam-pass-through holes are re-vaporized. A portion of the re-vaporized vapor deposition particles fly in a different direction from the penetration direction of the vapor deposition beam-pass-through holes, pass through the mask openings of the vapor deposition mask, and adhere to the substrate. In other words, even though the vapor deposition beam direction adjustment plate is provided in order to improve the directivity of the vapor deposition beam in Patent Document 4, it is difficult to control the directivity of the vapor deposition particles re-vaporized off the vapor deposition beam direction adjustment plate, as a result of which vapor deposition particles having undesired directivity adhere to the substrate. Therefore, if the substrate and the vapor deposition mask are spaced apart, the vapor deposition material adheres to an undesired portion of the substrate, and similarly to Patent Document 3 described above, blur occurs at the edge of the coating film formed on the substrate or an offset occurs in the formation position of the coating film.

It is an object of the present invention to provide a vapor deposition device and a vapor deposition method that are capable of forming a coating film in which edge blur is suppressed at a desired position on the substrate and that are applicable to large-sized substrates.

Also, it is an object of the present invention to provide a large-sized organic EL display device that has excellent reliability and display quality.

### Means for Solving Problem

The vapor deposition device of the present invention is a vapor deposition device that forms a coating film having a predetermined pattern on a substrate, and the vapor deposition device includes a vapor deposition unit including a vapor deposition source having at least one vapor deposition source opening, a vapor deposition mask disposed between the at least one vapor deposition source opening and the substrate, and a limiting plate unit that is disposed between the vapor deposition source and the vapor deposition mask and that includes a plurality of limiting plates disposed along a first direction, and a moving mechanism that moves one of the substrate and the vapor deposition unit relative to the other along a second direction orthogonal to a normal line direction of the substrate and the first direction in a state in which the substrate and the vapor deposition mask are spaced apart at a fixed interval. The coating film is formed by causing vapor deposition particles that have been discharged from the at least one vapor deposition source opening and passed through a limiting space between the limiting plates neighboring in the first direction and a plurality of mask openings formed in the vapor deposition mask to adhere onto the substrate. Side surfaces of the limiting plates that define the limiting space in the first direction are configured such that a portion having a dimension in the first direction of the limiting space wider than a narrowest portion having a narrowest dimension in the first direction of the limiting space is formed on at least the vapor deposition source side with respect to the narrowest portion.

The vapor deposition method of the present invention is a vapor deposition method including a vapor deposition step of forming a coating film having a predetermined pattern on a substrate by causing vapor deposition particles to adhere onto the substrate, and the vapor deposition step is performed by using the above vapor deposition device of the present invention.

An organic EL display device according to the present invention includes a light emitting layer formed by using the above vapor deposition method of the present invention.

### Effects of the Invention

According to the vapor deposition device and vapor deposition method of the present invention, the vapor deposition particles that have passed through the mask openings formed in the vapor deposition mask are caused to adhere to the substrate while one of the substrate and the vapor deposition unit is moved relative to the other, and therefore a vapor deposition mask that is smaller than the substrate can be used. It is therefore possible to form a coating film even on a large-sized substrate by vapor deposition.

The plurality of limiting plates provided between the vapor deposition source opening and the vapor deposition mask selectively capture the vapor deposition particles that have entered a limiting space between limiting plates neighboring in the first direction according to the incidence angle of the vapor deposition particles, and thus only the vapor deposition particles entering at a predetermined incidence angle or less enter the mask openings. As a result, the maximum incidence angle of the vapor deposition particles with respect to the substrate becomes small, and it is therefore possible to suppress blur that occurs at the edge of the coating film formed on the substrate.

Side surfaces of the limiting plates are configured such that a portion having a dimension in the first direction of the limiting space wider than a narrowest portion having a narrowest dimension in the first direction of the limiting space is formed on at least the vapor deposition source side with respect to the narrowest portion. Accordingly, most of the flight directions of the vapor deposition particles re-vaporized off the region of the side surfaces of the limiting plates on the vapor deposition source side with respect to the narrowest portion thereof can be caused to be pointed toward the opposite side to the substrate. Alternatively, it is possible to capture the vapor deposition particles re-vaporized off the region of the side surfaces of the limiting plates on the vapor deposition source side with respect to the narrowest portion thereof toward the substrate by causing the re-vaporized vapor deposition particles to collide with the side surfaces of the limiting plates before passing through the narrowest portion. Through these, the number of vapor deposition particles that are re-vaporized off the side surfaces of the limiting plates and adhere to the substrate can be reduced. As a result, a coating film in which edge blur is suppressed can be formed at a desired position on the substrate with high accuracy. Also, the need to frequently replace the limiting plate unit in order to reduce the amount of the vapor deposition material re-vaporized off the limiting plates is eliminated, and thus throughput at the time of mass production is improved, and productivity is improved.

The organic EL display device of the present invention includes a light emitting layer formed by using the vapor deposition method described above, and thus the positional offset of the light emitting layer and edge blur in the light emitting layer are suppressed. Accordingly, it is possible to provide an organic EL display device that has excellent reliability and display quality and that can be made in a large size.

### BRIEF DESCRIPTION OF DRAWINGS

FIG. 1 is a cross-sectional view showing a schematic configuration of an organic EL display device.

FIG. 2 is a plan view showing a configuration of pixels that constitute the organic EL display device shown in FIG. 1.

FIG. 3 is a cross-sectional view of a TFT substrate that constitutes the organic EL display device taken along the line 3-3 of FIG. 2.

FIG. 4 is a flowchart illustrating the steps of a process for manufacturing an organic EL display device in order.

FIG. 5 is a perspective view showing the basic configuration of a vapor deposition device according to a new vapor deposition method.

FIG. 6 is a front cross-sectional view of the vapor deposition device shown in FIG. 5 as viewed in a direction parallel to the traveling direction of a substrate.

FIG. 7 is a front cross-sectional view of the vapor deposition device shown in FIG. 5 without a limiting plate unit.

FIG. 8 is a cross-sectional view illustrating the cause of blur generated at both edges of a coating film.

FIG. 9A is an enlarged cross-sectional view showing how a coating film is formed on a substrate in the new vapor deposition method, and

FIG. 9B is an enlarged cross-sectional view illustrating the cause of the problem encountered with the new vapor deposition method.

FIG. 10 is a perspective view showing the basic configuration of a vapor deposition device according to Embodiment 1 of the present invention.

FIG. 11 is a front cross-sectional view of the vapor deposition device shown in FIG. 10 as viewed in a direction parallel to the traveling direction of a substrate.

FIG. 12 is an enlarged cross-sectional view illustrating the function of the side surfaces of the limiting plates in a vapor deposition device according to Embodiment 1 of the present invention.

FIG. 13 is an enlarged cross-sectional view of the vapor deposition device according to Embodiment 1 of the present invention including limiting plates having another side surface shape.

FIG. 14 is an enlarged cross-sectional view of the limiting plates having still another side surface shape in the vapor deposition device according to Embodiment 1 of the present invention.

FIG. 15 is an enlarged cross-sectional view of a vapor deposition device according to Embodiment 2 of the present invention, as viewed in a direction parallel to the traveling direction of a substrate.

FIGS. 16A to 16C are enlarged cross-sectional views of the limiting plates having another side surface shape in the vapor deposition device according to Embodiment 2 of the present invention.

FIG. 17 is an enlarged cross-sectional view of a vapor deposition device according to Embodiment 3 of the present invention, as viewed in a direction parallel to the traveling direction of a substrate.

FIG. 18A is an enlarged cross-sectional view of a vapor deposition device according to Embodiment 3 of the present invention, as viewed in a direction parallel to the traveling direction of a substrate, and

FIG. 18B is an enlarged cross-sectional view of the limiting plate shown in FIG. 18A.

FIG. 19 is an enlarged cross-sectional view of another limiting plate to be used in the vapor deposition device according to Embodiment 3 of the present invention.

### DESCRIPTION OF THE INVENTION

The vapor deposition device of the present invention is a vapor deposition device that forms a coating film having a predetermined pattern on a substrate, and the vapor deposition device includes a vapor deposition unit including a vapor deposition source having at least one vapor deposition source opening, a vapor deposition mask disposed between the at least one vapor deposition source opening and the substrate, and a limiting plate unit that is disposed between the vapor deposition source and the vapor deposition mask and that includes a plurality of limiting plates disposed along a first direction, and a moving mechanism that moves one of the substrate and the vapor deposition unit relative to the other along a second direction orthogonal to a normal line direction of the substrate and the first direction in a state in which the substrate and the vapor deposition mask are spaced apart at a fixed interval. The coating film is formed by causing vapor deposition particles that have been discharged from the at least one vapor deposition source opening and passed through a limiting space between the limiting plates neighboring in the first direction and a plurality of mask openings formed in the vapor deposition mask to adhere onto the substrate. Side surfaces of the limiting plates that define the limiting space in the first direction are configured such that a portion having a dimension in the first direction of the limiting space wider than a narrowest portion having a narrowest dimension in the first direction of the limiting space is formed on at least the vapor deposition source side with respect to the narrowest portion.

It is preferable that in the above-described vapor deposition device of the present invention, the side surfaces of the limiting plates opposing in the first direction across the limiting space are in plane symmetry relationship. Accordingly, it is possible to simplify the design of the flight paths of the vapor deposition particles that are discharged from the vapor deposition source openings and adhere to the substrate to form the coating film.

It is preferable that the narrowest portion is provided at edges of the side surfaces of the limiting plates on the vapor deposition mask side. Accordingly, the number of vapor deposition particles that are re-vaporized off the side surfaces of the limiting plates and adhere to the substrate can be further reduced.

It is preferable that the side surface of each of the limiting plates has, on the vapor deposition source side with respect to the narrowest portion, a surface that is inclined such that the dimension in the first direction of the limiting space increases as the distance from the narrowest portion increases along the normal line direction of the substrate. Accordingly, the flight directions of the vapor deposition particles re-vaporized off the surface inclined in this manner can be caused to be pointed toward the side opposite to the substrate. Accordingly, the number of vapor deposition particles that are re-vaporized off the side surfaces of the limiting plates and adhere to the substrate can be further reduced.

It is preferable that a recess is formed in a region of the side surface of each of the limiting plates, the region being located on the vapor deposition source side with respect to the narrowest portion. Accordingly, the flight directions of the vapor deposition particles re-vaporized off the region on the vapor deposition mask side with respect to the deepest portion of the recess can be caused to be pointed toward the side opposite to the substrate. Also, the region on the vapor deposition mask side with respect to the deepest portion of the recess is capable of capturing the vapor deposition particles re-vaporized off the region on the vapor deposition source side by causing the re-vaporized vapor deposition particles to collide therewith. Accordingly, the number of vapor deposition particles that are re-vaporized off the side surfaces of the limiting plates and adhere to the substrate can be further reduced. Also, the region on the vapor deposition source side with respect to the deepest portion of the recess is capable of receiving the vapor deposition material separated from the region on the vapor deposition mask side so as not to let the vapor deposition material fall on the vapor deposition source.

It is preferable that a first overhang protruding toward the limiting space is formed on the side surface of each of the limiting plates, and the narrowest portion is provided at tip ends of the first overhangs. Accordingly, the vapor deposition particles re-vaporized off the region on the vapor deposition source side with respect to the first overhang can be captured by causing the vapor deposition particles to collide with the first overhang. Therefore, the number of vapor deposition particles that are re-vaporized off the side surfaces of the limiting plates and adhere to the substrate can be further reduced. There is no particular limitation on the shape of the first overhang, and the shape can be set to an arbitrary shape such as a thin plate shape having a fixed thickness, a shape having a substantially wedge-shaped cross section in which the thickness is reduced toward the tip end thereof, and the like.

It is preferable that in the above-described vapor deposition device, the first overhang has, on the vapor deposition source side, a surface that is inclined such that the surface of the first overhang is closer to the vapor deposition source as the distance to the tip end decreases. Accordingly, it is possible to substantially completely prevent the vapor deposition particles re-vaporized off the surface of the first overhang on the vapor deposition source side from adhering to the substrate.

It is preferable that the first overhang has, at the tip end thereof, a surface that is inclined such that the dimension in the first direction of the limiting space increases as the distance to the vapor deposition source decreases. Accordingly, the flight directions of the vapor deposition particles re-vaporized off the distal surface of the first overhang can be caused to be pointed toward the side opposite to the substrate. Therefore, the number of vapor deposition particles that are re-vaporized off the side surfaces of the limiting plates and adhere to the substrate can be further reduced.

It is preferable that a second overhang protruding toward the limiting space is formed on the side surface of each of the limiting plates at a position on the vapor deposition source side with respect to the narrowest portion. Accordingly, because the vapor deposition material separated from the region of the side surface of the limiting plate on the vapor deposition mask side with respect to the second overhang can be received by the second overhang, it is possible to prevent the separated vapor deposition material from falling on the vapor deposition source. There is also no particular limitation on the shape of the second overhang, and the shape can be set to an arbitrary shape such as a thin plate shape having a fixed thickness, a shape having a substantially wedge-shaped cross section in which the thickness is reduced toward the tip end thereof, and the like.

It is preferable that each of the side surfaces of the limiting plates has a plurality of steps in a stepwise arrangement. Accordingly, the number of vapor deposition particles that are re-vaporized off the side surfaces of the limiting plates and adhere to the substrate can be further reduced.

It is preferable that side surfaces of the limiting plate unit that define the limiting space in the second direction are configured such that a portion having a dimension in the second direction of the limiting space wider than a second narrowest portion having a narrowest dimension in the second direction of the limiting space is formed on at least the vapor deposition source side with respect to the second narrowest portion. Accordingly, the number of vapor deposition particles that are re-vaporized off the side surfaces of the limiting plate unit and adhere to the substrate. can be reduced

It is preferable that the various preferred configurations to be applied to the side surfaces of the limiting plates can also be applied to the side surfaces of the limiting plate unit.

Hereinafter, the present invention will be described in detail by showing preferred embodiments. It should be noted, however, that the present invention is not limited to the following embodiments. For the sake of convenience of the description, the drawings referred to hereinafter show only the principal members required to describe the present invention in simplified form among the constituent members of the embodiments of the present invention. Accordingly, the present invention may include optional constituent members that are not shown in the following drawings. Also, the dimensions of the members in the drawings do not faithfully represent the actual dimensions or dimensional proportions of the constituent members.

(Configuration of Organic EL Display Device)

An example of an organic EL display device that can be manufactured by applying the present invention will be described. This organic EL display device is a bottom emission type organic EL display device in which light is extracted from the TFT substrate side and that displays full color images by controlling light emission of red (R), green (G) and blue (B) pixels (sub-pixels).

First, the overall configuration of the organic EL display device will be described below.

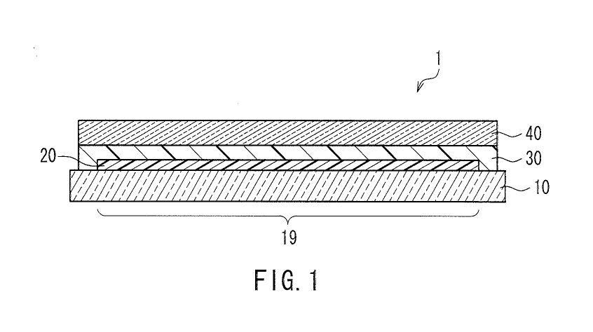

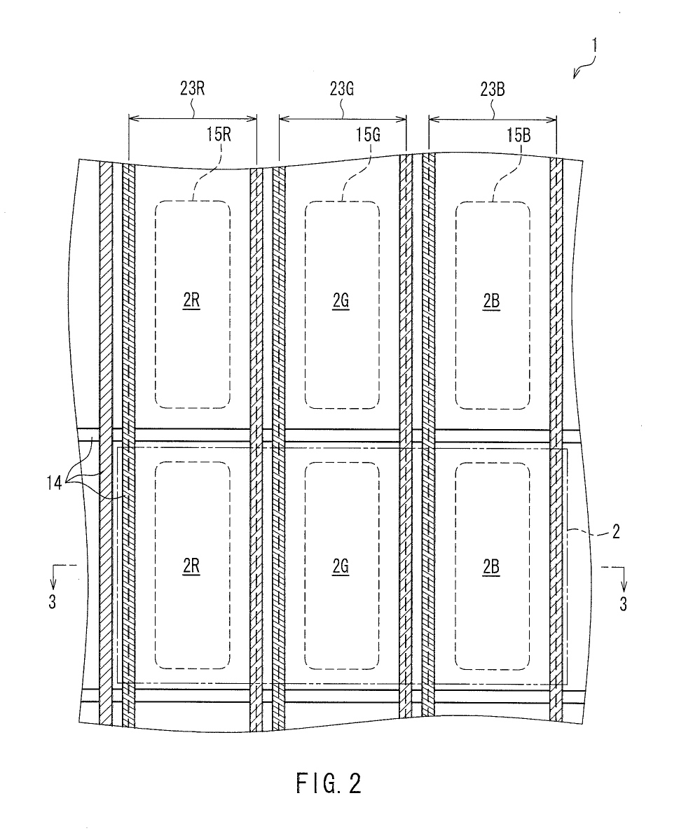

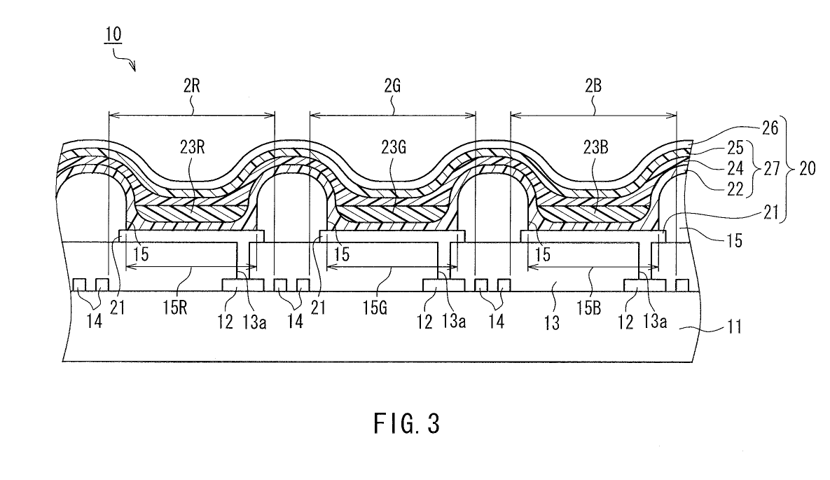

FIG. 1 is a cross-sectional view showing a schematic configuration of the organic EL display device. FIG. 2 is a plan view showing a configuration of pixels that constitute the organic EL display device shown in FIG. 1. FIG. 3 is a cross-sectional view of a TFT substrate that constitutes the organic EL display device, taken along the line III-III of FIG. 2.

As shown in FIG. 1, the organic EL display device 1 has a configuration in which, on a TFT substrate 10 provided with a TFT 12 (see FIG. 3), an organic EL element 20 connected to the TFT 12, an adhesive layer 30 and a sealing substrate 40 are provided in this order. A display region 19 in which images are displayed is located in the center of the organic EL display device 1, and the organic EL element 20 is disposed within the display region 19.

The organic EL element 20 is enclosed between a pair of substrates, namely, the TFT substrate 10 and the sealing substrate 40, by the TFT substrate 10 having the organic EL element 20 laminated thereon being bonded to the sealing substrate 40 with the use of the adhesive layer 30. By the organic EL element 20 being enclosed between the TFT substrate 10 and the sealing substrate 40 as described above, oxygen and moisture are prevented from entering the organic EL element 20 from the outside.

As shown in FIG. 3, the TFT substrate 10 includes, as a support substrate, a transparent insulating substrate 11 such as a glass substrate, for example. In the case of a top emission type organic EL display device, however, the insulating substrate 11 is not necessarily transparent.

As shown in FIG. 2, on the insulating substrate 11, a plurality of wires 14 are provided that include a plurality of gate lines provided in the horizontal direction and a plurality of signal lines intersecting the gate lines and provided in the vertical direction. A gate line driving circuit (not shown) that drives the gate lines is connected to the gate lines, and a signal line driving circuit (not shown) that drives the signal lines are connected to the signal lines. On the insulating substrate 11, red (R), green (G) and blue (B) sub-pixels 2R, 2G and 2B made of the organic EL element 20 are disposed in a matrix in their respective regions surrounded by the wires 14.

The sub-pixels 2R emit red light, the sub-pixels 2G emit green light, and the sub-pixels 2B emit blue light. Sub-pixels of the same color are disposed in a column direction (up-down direction in FIG. 2) and a repeating unit consisting of sub-pixels 2R, 2G and 2B is repeatedly disposed in a row direction (right-left direction in FIG. 2). The sub-pixels 2R, 2G and 2B constituting a repeating unit in the row direction constitute a pixel 2 (specifically, a single pixel).

The sub-pixels 2R, 2G and 2B respectively include light emitting layers 23R, 23G and 23B that emit respective colors. The light emitting layers 23R, 23G and 23B are provided to extend in stripes in the column direction (up-down direction in FIG. 2).

A configuration of the TFT substrate 10 will be described.

As shown in FIG. 3, the TFT substrate 10 includes, on the transparent insulating substrate 11 such as a glass substrate, the TFT 12 (switching element), the wires 14, an inter-layer film 13 (interlayer insulating film, planarized film), an edge cover 15, and so on.

The TFT 12 functions as a switching element that controls light emission of the sub-pixels 2R, 2G and 2B, and is provided for each of the sub-pixels 2R, 2G and 2B. The TFT 12 is connected to the wires 14.

The inter-layer film 13 also functions as a planarized film, and is laminated over the display region 19 of the insulating substrate 11 so as to cover the TFT 12 and the wires 14.

A first electrode 21 is formed on the inter-layer film 13. The first electrode 21 is electrically connected to the TFT 12 via a contact hole 13a formed in the inter-layer film 13.

The edge cover 15 is formed on the inter-layer film 13 so as to cover pattern ends of the first electrode 21. The edge cover 15 is an insulating layer for preventing short-circuiting between the first electrode 21 and a second electrode 26 that constitute the organic EL element 20 caused by an organic EL layer 27 becoming thin or the occurrence of electric field concentration at the pattern ends of the first electrode 21.

The edge cover 15 has openings 15R, 15G and 15B for the sub-pixels 2R, 2G and 2B. The openings 15R, 15G and 15B of the edge cover 15 serve as light emitting regions of the sub-pixels 2R, 2G and 2B. To rephrase, the sub-pixels 2R, 2G and 2B are partitioned by the edge cover 15 that is insulative. The edge cover 15 also functions as an element separation film.

The organic EL element 20 will be described.

The organic EL element 20 is a light emitting element capable of emitting highly bright light by low voltage direct current driving, and includes the first electrode 21, the organic EL layer 27 and the second electrode 26 in this order.

The first electrode 21 is a layer having a function of injecting (supplying) holes into the organic EL layer 27. As described above, the first electrode 21 is connected to the TFT 12 via the contact hole 13a.

As shown in FIG. 3, the organic EL layer 27 includes, between the first electrode 21 and the second electrode 26, a hole injection and transport layer 22, the light emitting layers 23R, 23G, 23B, an electron transport layer 24 and an electron injection layer 25 in this order from the first electrode 21 side.

In the present embodiment, the first electrode 21 serves as a positive electrode and the second electrode 26 serves as a negative electrode, but the first electrode 21 may serve as a negative electrode and the second electrode 26 may serve as a positive electrode. In this case, the order of the layers constituting the organic EL layer 27 is reversed.

The hole injection and transport layer 22 functions both as a hole injection layer and a hole transport layer. The hole injection layer is a layer having a function of enhancing the efficiency of injecting holes into the organic EL layer 27. The hole transport layer is a layer having a function of enhancing the efficiency of transporting holes to the light emitting layers 23R, 23G and 23B. The hole injection and transport layer 22 is formed uniformly over the display region 19 in the TFT substrate 10 so as to cover the first electrode 21 and the edge cover 15.

In the present embodiment, the hole injection and transport layer 22 in which a hole injection layer and a hole transport layer are integrated together is provided, but the present invention is not limited thereto, and the hole injection layer and the hole transport layer may be formed as independent layers.

On the hole injection and transport layer 22, the light emitting layers 23R, 23G and 23B are formed correspondingly to the columns of the sub-pixels 2R, 2G and 2B so as to cover the openings 15R, 15G and 15B of the edge cover 15, respectively. The light emitting layers 23R, 23G and 23B are layers having a function of emitting light by recombining holes injected from the first electrode 21 side and electrons injected from the second electrode 26 side. The light emitting layers 23R, 23G and 23B each contain a material having a high light-emission efficiency such as a low-molecular fluorescent dye or a metal complex.

The electron transport layer 24 is a layer having a function of enhancing the efficiency of transporting electrons from the second electrode 26 to the light emitting layers 23R, 23G and 23B.

The electron injection layer 25 is a layer having a function of enhancing the efficiency of injecting electrons from the second electrode 26 to the organic EL layer.

The electron transport layer 24 is formed uniformly over the display region 19 in the TFT substrate 10 such that it is on the light emitting layers 23R, 23G and 23B and the hole injection and transport layer 22 so as to cover the light emitting layers 23R, 23G and 23B and the hole injection and transport layer 22. Likewise, the electron injection layer 25 is formed uniformly over the display region 19 in the TFT substrate 10 such that it is on the electron transport layer 24 so as to cover the electron transport layer 24.

In the present embodiment, the electron transport layer 24 and the electron injection layer 25 are provided as independent layers, but the present invention is not limited thereto, and they may be provided as a single layer (specifically, an electron transport and injection layer) in which the electron transport layer 24 and the electron injection layer 25 are integrated together.

The second electrode 26 is a layer having a function of injecting electrons into the organic EL layer 27. The second electrode 26 is formed uniformly over the display region 19 in the TFT substrate 10 such that it is on the electron injection layer 25 so as to cover the electron injection layer 25.

An organic layer other than the light emitting layers 23R, 23G and 23B is not essential to the organic EL layer 27, and may be selected or omitted according to the characteristics required of the organic EL element 20. The organic EL layer 27 may further include a carrier blocking layer if necessary. By adding a hole blocking layer serving as a carrier blocking layer between the electron transport layer 24 and the light emitting layer 23R, 23G, 23B, for example, it is possible to prevent holes from escaping to the electron transport layer 24, whereby light-emission efficiency can be improved.

(Manufacturing Method for Organic EL Display Device)

A method for manufacturing an organic EL display device 1 will be described below.

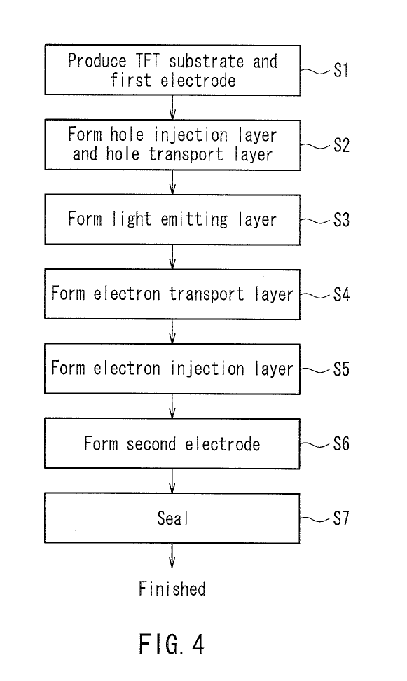

FIG. 4 is a flowchart illustrating the steps of a process for manufacturing the above-described organic EL display device 1 in order.

As shown in FIG. 4, the method for manufacturing an organic EL display device 1 according to the present embodiment includes, for example, a TFT substrate/first electrode producing step S1, a hole injection layer/hole transport layer forming step S2, a light emitting layer forming step S3, an electron transport layer forming step S4, an electron injection layer forming step S5, a second electrode forming step S6 and a sealing step S7 in this order.

Each step of FIG. 4 will be described below. It should be noted, however, that the dimensions, materials and shapes of the constituent elements described below are merely examples, and the present invention is not limited thereto. Also, in the present embodiment, the first electrode 21 is used as a positive electrode and the second electrode 26 is used as a negative electrode, but in the case where the first electrode 21 is used as a negative electrode and the second electrode 26 is used as a positive electrode, the order of the layers laminated in the organic EL layer is reversed from that discussed below. Likewise, the materials for constituting the first electrode 21 and the second electrode 26 are also reversed from those discussed below.

First, a TFT 12, wires 14 and the like are formed on an insulating substrate 11 by a known method. As the insulating substrate 11, for example, a transparent glass substrate, plastic substrate or the like can be used. As an example, a rectangular glass plate having a thickness of about 1 mm and longitudinal and transverse dimensions of 500×400 mm can be used as the insulating substrate 11.

Next, a photosensitive resin is applied onto the insulating substrate 11 so as to cover the TFT 12 and the wires 14, and patterning is performed using a photolithography technique to form an inter-layer film 13. As a material for the inter-layer film 13, for example, an insulating material such as acrylic resin or polyimide resin can be used. Generally, polyimide resin is not transparent but colored. For this reason, when manufacturing a bottom emission type organic EL display device 1 as shown FIG. 3, it is preferable to use a transparent resin such as acrylic resin for the inter-layer film 13. There is no particular limitation on the thickness of the inter-layer film 13 as long as irregularities in the upper surface of the TFT 12 can be eliminated. As an example, an inter-layer film 13 having a thickness of about 2 μm can be formed by using acrylic resin.

Next, contact holes 13a for electrically connecting the first electrode 21 to the inter-layer film 13 are formed.

Next, a first electrode 21 is formed on the inter-layer film 13. Specifically, a conductive film (electrode film) is formed on the inter-layer film 13. Next, a photoresist is applied onto the conductive film and patterning is performed by using a photolithography technique, after which the conductive film is etched using ferric chloride as an etching solution. After that, the photoresist is stripped off using a resist stripping solution, and the substrate is washed. A first electrode 21 in a matrix is thereby obtained on the inter-layer film 13.

Examples of conductive film-forming materials that can be used for the first electrode 21 include transparent conductive materials such as ITO (indium tin oxide), IZO (indium zinc oxide) and gallium-added zinc oxide (GZO); and metal materials such as gold (Au), nickel (Ni) and platinum (Pt).

As the method for laminating conductive films, it is possible to use a sputtering method, a vacuum vapor deposition method, a CVD (chemical vapor deposition) method, a plasma CVD method, a printing method or the like can be used.

As an example, a first electrode 21 having a thickness of about 100 nm can be formed by a sputtering method using ITO.

Next, an edge cover 15 having a predetermined pattern is formed. The edge cover 15 can be formed by, for example, patterning performed in the same manner as performed for the inter-layer film 13, using the same insulating materials as those listed for the edge cover 15. As an example, an edge cover 15 having a thickness of about 1 μm can be formed using acrylic resin.

Through the above processing, the TFT substrate 10 and the first electrode 21 are produced (Step S1).

Next, the TFT substrate 10 that has undergone step S1 is baked under reduced pressure for the purpose of dehydration and then subjected to an oxygen plasma treatment in order to wash the surface of the first electrode 21.

Next, on the TFT substrate 10, a hole injection layer and a hole transport layer (in the present embodiment, a hole injection and transport layer 22) is formed over the display region 19 in the TFT substrate 10 by a vapor deposition method (S2).

Specifically, an open mask having an opening corresponding to the entire display region 19 is closely fixed to the TFT substrate 10. Materials for forming a hole injection layer and a hole transport layer are deposited over the display region 19 in the TFT substrate 10 through the opening of the open mask while the TFT substrate 10 and the open mask are rotated together.

As noted above, the hole injection layer and the hole transport layer may be integrated into a single layer, or may be independent layers. Each layer has a thickness of, for example, 10 to 100 nm.

Examples of materials for the hole injection layer and the hole transport layer include benzine, styryl amine, triphenyl amine, porphyrin, triazole, imidazole, oxadiazole, polyarylalkane, phenylene diamine, arylamine, oxazole, anthracene, fluorenone, hydrazone, stilbene, triphenylene, azatriphenylene and derivatives thereof, heterocyclic or linear conjugated monomers, oligomers or polymers, such as polysilane-based compounds, vinylcarbazole-based compounds, thiophene-based compounds, aniline-based compounds and the like.

As an example, a hole injection and transport layer 22 having a thickness of 30 nm can be formed using 4,4′-bis[N-(1-naphthyl)-N-phenylamino]biphenyl (α-NPD).

Next, on the hole injection and transport layer 22, light emitting layers 23R, 23G and 23B are formed in stripes so as to cover openings 15R, 15G and 15B in the edge cover 15 (S3). The light emitting layers 23R, 23G and 23B are deposited such that respective colors, namely, red, green and blue are applied to corresponding predetermined regions (vapor deposition by color).

As materials for the light emitting layers 23R, 23G and 23B, materials having a high light-emission efficiency such as low-molecular fluorescent dyes or metal complexes can be used. Examples thereof include anthracene, naphthalene, indene, phenanthrene, pyrene, naphthacene, triphenylene, anthracene, perylene, picene, fluoranthene, acephenanthrylene, pentaphene, pentacene, coronene, butadiene, coumarin, acridine, stilbene and derivatives thereof, tris(8-quinolinolato)aluminum complex, bis(benzoquinolinato)beryllium complex, tri(dibenzoylmethyl)phenanthroline europium complex, ditolyl vinyl biphenyl and the like.

The light emitting layers 23R, 23G and 23B can have a thickness of, for example, 10 to 100 nm.

The vapor deposition method and the deposition device of the present invention can be used particularly suitably in vapor deposition by color for forming light emitting layers 23R, 23G and 23B. The method for forming light emitting layers 23R, 23G and 23B using the present invention will be described later in detail.

Next, an electron transport layer 24 is formed over the display region 19 in the TFT substrate 10 so as to cover the hole injection and transport layer 22 and the light emitting layers 23R, 23G and 23B by a vapor deposition method (S4). The electron transport layer 24 can be formed in the same manner as in the hole injection layer/hole transport layer forming step (S2) described above.

Next, an electron injection layer 25 is formed over the display region 19 in the TFT substrate 10 so as to cover the electron transport layer 24 by a vapor deposition method (S5). The electron injection layer 25 can be formed in the same manner as in the hole injection layer/hole transport layer forming step (S2) described above.

Examples of materials for the electron transport layer 24 and the electron injection layer 25 include quinoline, perylene, phenanthroline, bisstyryl, pyrazine, triazole, oxazole, oxadiazole, fluorenone, and derivatives and metal complexes thereof, LiF (lithium fluoride) and the like.

As noted above, the electron transport layer 24 and the electron injection layer 25 may be formed as a single layer in which these layers are integrated together, or may be formed as independent layers. Each layer has a thickness of, for example, 1 to 100 nm. The total thickness of the electron transport layer 24 and the electron injection layer 25 is, for example, 20 to 200 nm.

As an example, an electron transport layer 24 having a thickness of 30 nm can be formed using Alq (tris(8-hydroxyquinoline)aluminum), and an electron injection layer 25 having a thickness of 1 nm can be formed using LiF (lithium fluoride).

Next, a second electrode 26 is formed over the display region 19 in the TFT substrate 10 so as to cover the electron injection layer 25 by a vapor deposition method (S6). The second electrode 26 can be formed in the same manner as in the hole injection layer/hole transport layer forming step (S2) described above. The material (electrode material) for the second electrode 26 is preferably a metal having a small work function, or the like. Examples of such electrode materials include magnesium alloy (MgAg and the like), aluminum alloy (AlLi, AlCa, AlMg and the like), metal calcium, and the like. The second electrode 26 has a thickness of, for example, 50 to 100 nm. As an example, a second electrode 26 having a thickness of 50 nm can be formed using aluminum.

On the second electrode 26, a protective film may be formed so as to cover the second electrode 26, in order to prevent oxygen and moisture from entering the organic EL element 20 from the outside. As the material for the protective film, an insulating or conductive material can be used. Examples thereof include silicon nitride and silicon oxide. The protective film has a thickness of, for example, 100 to 1000 nm.

Through the above processing, the organic EL element 20 including the first electrode 21, the organic EL layer 27 and the second electrode 26 can be formed on the TFT substrate 10.

Next, as shown in FIG. 1, the TFT substrate 10 having the organic EL element 20 formed thereon is bonded to a sealing substrate 40 by using an adhesive layer 30 so as to enclose the organic EL element 20. As the sealing substrate 40, for example, an insulating substrate, such as a glass substrate or a plastic substrate, having a thickness of 0.4 to 1.1 mm can be used.

In this manner, an organic EL display device 1 is obtained.

In the organic EL display device 1, when the TFT 12 is turned on by input of signals from the wires 14, holes are injected from the first electrode 21 into the organic EL layer 27. On the other hand, electrons are injected from the second electrode 26 into the organic EL layer 27. The holes and the electrons are recombined in the light emitting layers 23R, 23G and 23B and emit predetermined color light when deactivating energy. By controlling emitting brightness of each of the sub-pixels 2R, 2G and 2B, a predetermined image can be displayed on the display region 19.

Hereinafter, S3, which is the step of forming light emitting layers 23R, 23G and 23B by vapor deposition by color, will be described.

(New Vapor Deposition Method)

The present inventors investigated, as the method for forming light emitting layers 23R, 23G and 23B by vapor deposition by color, a new vapor deposition method (hereinafter referred to as the “new vapor deposition method”) in which vapor deposition is performed while a substrate is moved with respect to a vapor deposition source and a vapor deposition mask, instead of the vapor deposition method as disclosed in Patent Documents 1 and 2 in which a mask having the same size as a substrate is fixed to the substrate at the time of vapor deposition.

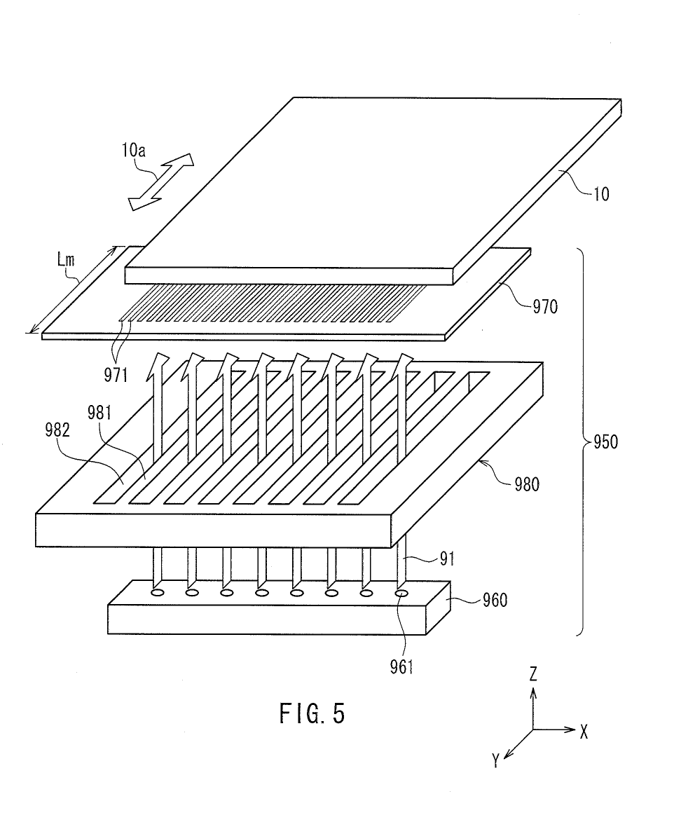

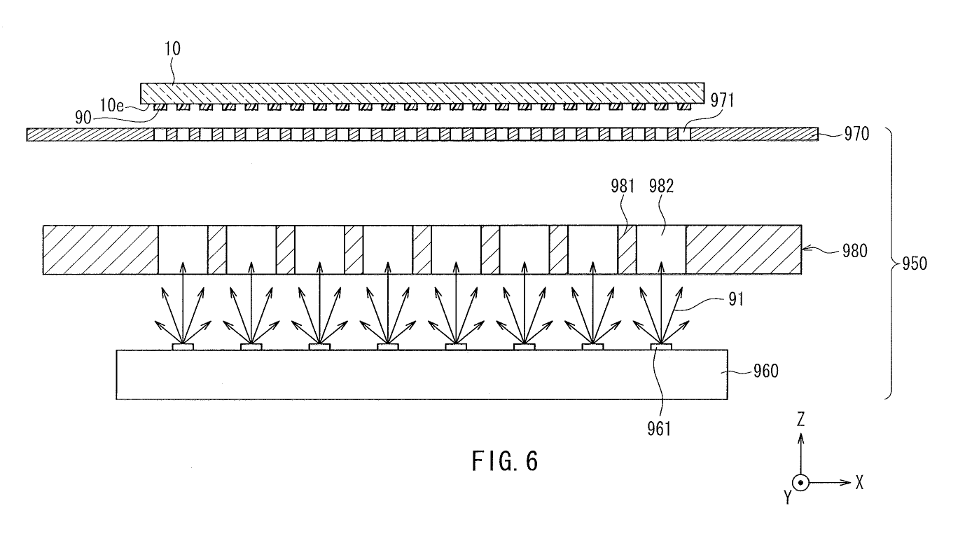

FIG. 5 is a perspective view showing the basic configuration of the vapor deposition device according to the new vapor deposition method. FIG. 6 is a front cross-sectional view of the vapor deposition device shown in FIG. 5.

A vapor deposition source 960, a vapor deposition mask 970, and a limiting plate unit 980 disposed therebetween constitute a vapor deposition unit 950. The relative positions of the vapor deposition source 960, the limiting plate unit 980, and the vapor deposition mask 970 are constant. The substrate 10 moves along an arrow 10a at a constant speed with respect to the vapor deposition mask 970 on the opposite side from the vapor deposition source 960. For the sake of convenience of the description given below, an XYZ orthogonal coordinate system is set in which a horizontal axis parallel to the movement direction 10a of the substrate 10 is defined as the Y axis, a horizontal axis perpendicular to the Y axis is defined as the X axis, and a vertical axis perpendicular to the X axis and the Y axis is defined as the Z axis. The Z axis is parallel to the normal line direction of the deposition surface 10e of the substrate 10.

A plurality of vapor deposition source openings 961 that discharge vapor deposition particles 91 are formed on the upper surface of the vapor deposition source 960. The plurality of vapor deposition source openings 961 are arranged at a fixed pitch along a straight line parallel to the X axis.

The limiting plate unit 980 has a plurality of limiting plates 981. The major surface (the surface having the largest area) of each of the limiting plates 981 is parallel to the YZ plane. The plurality of limiting plates 981 are arranged parallel to the direction in which the plurality of vapor deposition source openings 961 are arranged (that is, the X axis direction), at a fixed pitch. A space between limiting plates 981 neighboring in the X axis direction that penetrates the limiting plate unit 980 in the Z axis direction is referred to as a limiting space 982.

A plurality of mask openings 971 are formed in the vapor deposition mask 970. The plurality of mask openings 971 are arranged along the X axis direction.

The vapor deposition particles 91 discharged from the vapor deposition source openings 961 pass through the limiting spaces 982, further pass through the mask openings 971, and adhere to the substrate 10 to form a stripe-shaped coating film 90 parallel to the Y axis. Vapor deposition is repeatedly performed for each color of light emitting layers 23R, 23G and 23B, whereby vapor deposition by color for forming light emitting layers 23R, 23G and 23B can be performed.

According to this new vapor deposition method, a dimension Lm of the vapor deposition mask 970 in the movement direction 10a of the substrate 10 can be set irrespective of a dimension of the substrate 10 in the same direction. This enables the use of a vapor deposition mask 970 that is smaller than the substrate 10. Accordingly, even if the substrate 10 is made large, the vapor deposition mask 970 does not need to be made large, and therefore the problem in that the vapor deposition mask 970 is bent by its own weight or being extended does not occur. Also, the vapor deposition mask 970 and a frame or the like for holding the vapor deposition mask 970 do not need to be made big and heavy. Accordingly, the problems encountered with the conventional vapor deposition methods disclosed in Patent Documents 1 and 2 are solved, and large-sized substrates can be subjected to vapor deposition by color.

Effects of the new vapor deposition method on the limiting plate unit 980 are now described.

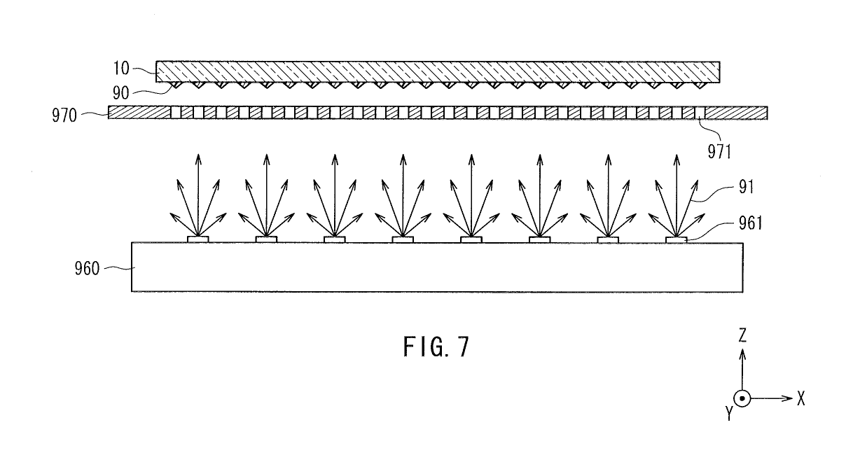

FIG. 7 is a cross-sectional view showing the vapor deposition device according to the new vapor deposition method similar to FIG. 6 except that the limiting plate unit 980 is omitted.

As shown in FIG. 7, the vapor deposition particles 91 from each vapor deposition source opening 961 are discharged with a certain spread (directivity). Specifically, in FIG. 7, the number of vapor deposition particles 91 discharged from each vapor deposition source opening 961 is the greatest in a direction upward from the vapor deposition source opening 961 (the Z axis direction) and gradually decreases as the angle (departure angle) formed with respect to the straight upward direction increases. The vapor deposition particles 91 discharged from the vapor deposition source openings 961 travel straight in their discharged directions. In FIG. 7, the flow of vapor deposition particles 91 discharged from the vapor deposition source openings 961 is conceptually indicated by arrows. The length of the arrows corresponds to the number of vapor deposition particles. Accordingly, each mask opening 971 mostly receives, but not necessarily limited thereto, the vapor deposition particles 91 discharged from the vapor deposition source opening 961 located directly below the mask opening 971 and also receives the vapor deposition particles 91 discharged from the vapor deposition source openings 961 located obliquely downward.

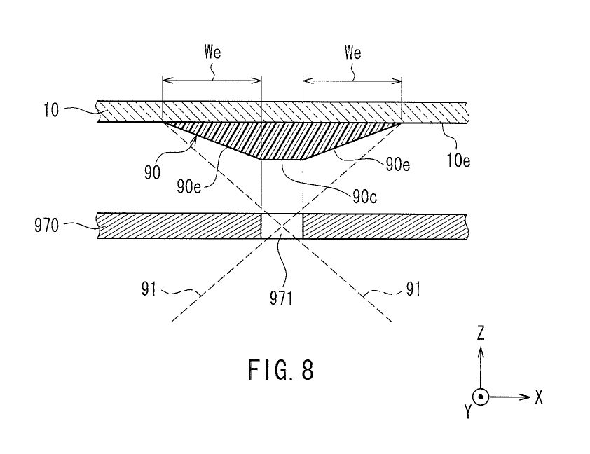

FIG. 8 is a cross-sectional view of a coating film 90 formed on a substrate 10 with vapor deposition particles 91 that have passed through a mask opening 971 in the vapor deposition device of FIG. 7, as viewed in a plane perpendicular to the Y axis as in FIG. 7. As described above, the vapor deposition particles 91 coming from various directions pass through the mask opening 971. The number of vapor deposition particles 91 that reach a deposition surface 10e of the substrate 10 is the greatest in a region directly above the mask opening 971 and gradually decreases as the position gets farther away therefrom. Accordingly, as shown in FIG. 8, on the deposition surface 10e of the substrate 10, a coating film main portion 90c having a large and substantially constant thickness is formed in the region where the mask opening 971 is projected onto the substrate 10 from directly above, and blur portions 90e that are gradually thinner as the position gets farther away from the coating film main portion 90c are formed on both sides of the coating film main portion 90c. Then, the blur portions 90e cause blur at the edge of the coating film 90.

In order to reduce the width We of the blur portion 90e, a space between the vapor deposition mask 970 and the substrate 10 needs only be reduced. However, because it is necessary to move the substrate 10 relative to the vapor deposition mask 970, it is not possible to reduce the space between the vapor deposition mask 970 and the substrate 10 to zero.

If the blur portion 90e extends to the neighboring light emitting layer region having a different color due to an increase in the width We of the blur portion 90e, it causes “color mixing” or degradation of the characteristics of the organic EL element. In order to prevent the blur portion 90e from extending to the neighboring light emitting layer region having a different color, so as to not cause color mixing, it is necessary to reduce the opening width of pixels (the pixels referring to the sub-pixels 2R, 2G and 2B shown in FIG. 2) or to increase the pixel pitch so as to increase the non-light-emitting region. However, if the opening width of the pixels is reduced, the light-emitting region will be small, causing a reduction in brightness. If the current density is increased in order to obtain the required brightness, the organic EL element will have a short service life and easily be damaged, causing a reduction in reliability. If, on the other hand, the pixel pitch is increased, display of high definition images cannot be achieved, reducing the quality of display.

In contrast, with a new vapor deposition method, as shown in FIG. 6, the limiting plate unit 980 is provided between the vapor deposition source 960 and the vapor deposition mask 970.

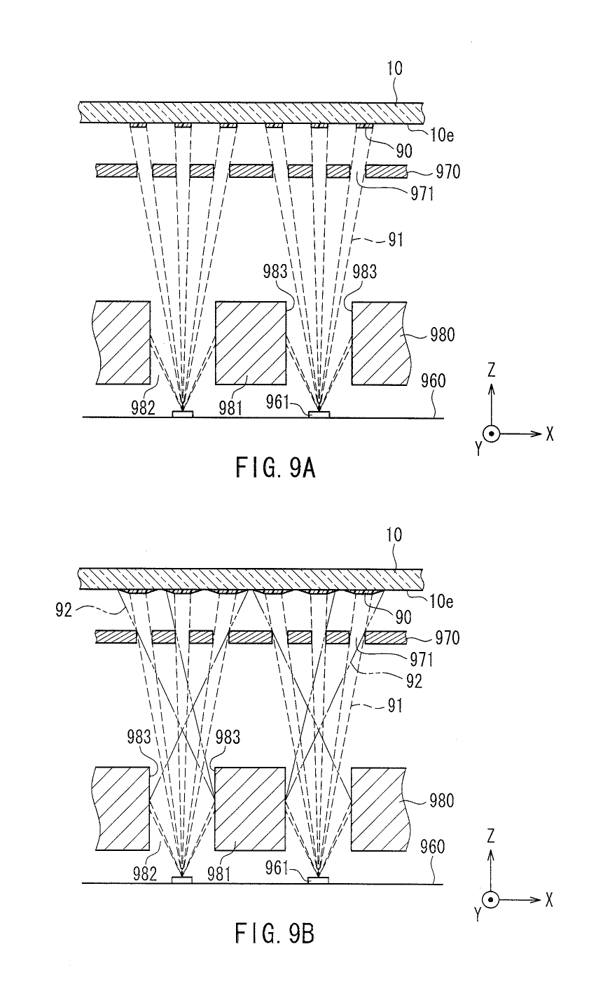

FIG. 9A is an enlarged cross-sectional view showing how the coating film 90 is formed on the substrate 10 in the new vapor deposition method. In the present example, one vapor deposition source opening 961 is disposed for one limiting space 982, and the vapor deposition source opening 961 is disposed at the central position of a pair of the limiting plates 981 in the X axis direction. The representative flight paths of the vapor deposition particles 91 discharged from the vapor deposition source openings 961 are indicated by dashed lines. Among the vapor deposition particles 91 discharged from the vapor deposition source opening 961 with a certain spread (directivity), those passing through the limiting space 982 directly above the vapor deposition source opening 961 and then passing through the mask opening 971 adhere to the substrate 10 so as to form the coating film 90. On the other hand, the vapor deposition particles 91 having a large speed vector component in the X axis direction collide with and adhere to side surfaces 983 of the limiting plates 981 that define the limiting space 982, and therefore cannot pass through limiting spaces 982 and cannot reach the mask openings 971. That is, the limiting plates 981 limit the incidence angle of the vapor deposition particles 91 entering the mask openings 971. As used herein, “incidence angle” of the vapor deposition particles 91 with respect to a mask opening 971 is defined as the angle formed between the flight direction of the vapor deposition particles 91 entering the mask opening 971 and the Z axis on a projection onto the XZ plane.

As described above, the directivity of the vapor deposition particles 91 in the X axis direction can be improved by using the limiting plate unit 980 including the plurality of limiting plates 981. Accordingly, the width We of the blur portion 90e can be reduced.

With the above-described conventional vapor deposition method described in Patent Document 3, a member corresponding to the limiting plate unit 980 of the new vapor deposition method is not used. Also, vapor deposition particles are discharged from a single slot-shaped opening of the vapor deposition source that extends along the direction orthogonal to the relative movement direction of the substrate. With this configuration, the incidence angle of the vapor deposition particles with respect to the mask opening becomes larger than that in the new vapor deposition method, and therefore detrimental blur occurs at the edge of the coating film.

As described above, according to the new vapor deposition method, the width We of the blur portion 90e at the edge of the coating film 90 to be formed on the substrate 10 can be reduced. Therefore, vapor deposition by color for forming light emitting layers 23R, 23G and 23B using the new vapor deposition method can prevent color mixing from occurring. Accordingly, the pixel pitch can be reduced, and in this case, it is possible to provide an organic EL display device that is capable of displaying high definition images. Meanwhile, the light-emitting region may be enlarged without changing the pixel pitch, and in this case, it is possible to provide an organic EL display device that is capable of displaying high definition images. Also, because it is not necessary to increase the current density in order to increase the brightness, the organic EL element does not have a short service life and is not easily damaged, and a reduction in reliability can be prevented.

However, as a result of examinations, the present inventors found that the new vapor deposition method is problematic in that when the coating film 90 is formed on the substrate 10 actually using the new vapor deposition method, the width We of the blur portion 90e at the edge of the coating film 90 cannot be reduced as assumed. Also, the inventors found that there is a problem in that the vapor deposition material adheres to an undesired portion of the deposition surface 10e of the substrate 10. Moreover, they found that these problems are caused by the vapor deposition material that has adhered to the side surfaces 983 of the limiting plate unit 980 being re-vaporized.

This will be described below.

FIG. 9B is an enlarged cross-sectional view illustrating the cause of the above-described problems in the new vapor deposition method. As shown in FIG. 9B, the limiting plate unit 980 is disposed in the vicinity of the vapor deposition source 960 that is kept at high temperature so as to oppose the vapor deposition source 960, and thus is heated from receiving the radiant heat from the vapor deposition source 960. Therefore, depending on the conditions such as the amount of the vapor deposition material adhering to the side surfaces 983 of the limiting plates 981, the degree of vacuum in the periphery, and the like, the vapor deposition material that has adhered to the side surfaces 983 may be re-vaporized as vapor deposition particles. There are various flight directions of the re-vaporized vapor deposition particles, and a portion of the vapor deposition particles 92 pass through the mask openings 971 and adhere to an undesired position on the deposition surface 10e of the substrate 10, as indicated by double-dot-dashed lines in FIG. 9B. As a result, blur may occur at the edge of the coating film 90, and an offset may occur in the formation position of the coating film.

In order to reduce the re-vaporization of the vapor deposition material off the limiting plates 981, the limiting plate unit 980 need only be frequently replaced. However, this leads to an increase in the frequency of maintenance, a drop in the throughput at the time of mass production, and a drop in the productivity.

The problem of the new vapor deposition method is the same as the problem encountered with the vapor deposition device of Patent Document 4 described above, in terms of the principle of the occurrence.

The present inventors conducted an in-depth investigation to solve the above problems encountered with the new vapor deposition method and the present invention has been accomplished. Hereinafter, the present invention will be described using preferred embodiments.

### Embodiment 1

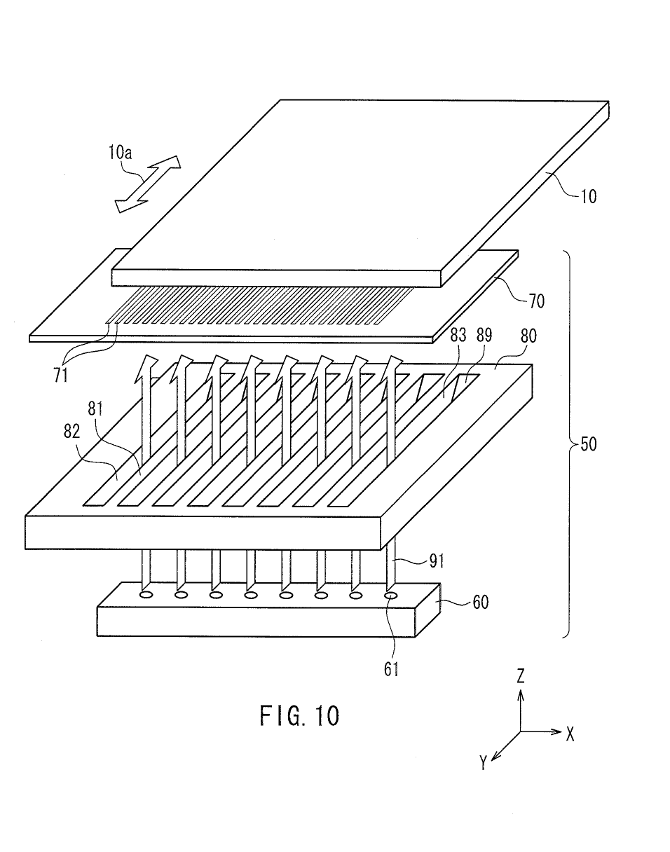

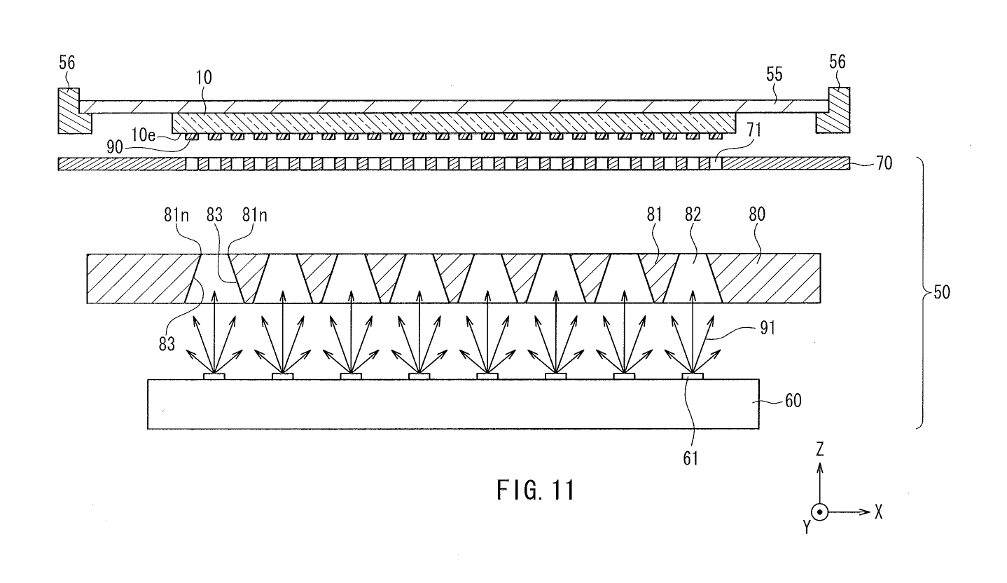

FIG. 10 is a perspective view showing the basic configuration of a vapor deposition device according to Embodiment 1 of the present invention. FIG. 11 is a front cross-sectional view of the vapor deposition device shown in FIG. 10.

A vapor deposition source 60, a vapor deposition mask 70, and a limiting plate unit 80 disposed therebetween constitute a vapor deposition unit 50. The substrate 10 moves along an arrow 10a at a constant speed with respect to the vapor deposition mask 70 on the opposite side from the vapor deposition source 60. For the sake of convenience of the description given below, an XYZ orthogonal coordinate system is set in which a horizontal axis parallel to the movement direction 10a of the substrate 10 is defined as the Y axis, a horizontal axis perpendicular to the Y axis is defined as the X axis, and a vertical axis perpendicular to the X axis and the Y axis is defined as the Z axis. The Z axis is parallel to the normal line direction of the deposition surface 10e of the substrate 10. To facilitate the description, the side to which the arrow indicating the Z axis points (the upper side of FIG. 11) is referred to the “upper side”.

The vapor deposition source 60 has a plurality of vapor deposition source openings 61 in its upper surface (the surface opposing the vapor deposition mask 70). The plurality of vapor deposition source openings 61 are arranged at a fixed pitch along a straight line parallel to the X axis direction. Each vapor deposition source opening 61 has a nozzle shape that is upwardly open parallel to the Z axis and discharges vapor deposition particles 91, which are a light emitting layer-forming material, toward the vapor deposition mask 70.

The vapor deposition mask 70 is a plate-shaped piece that has a major surface (the surface having the largest area) parallel to the XY plane and in which a plurality of mask openings 71 are formed along the X axis direction at different positions in the X axis direction. The mask openings 71 are through holes that penetrate the vapor deposition mask 70 in the Z axis direction. In the present embodiment, each mask opening 71 has an opening shape having a slot shape that is parallel to the Y axis, but the present invention is not limited thereto. All of the mask openings 71 may have the same shape and dimensions, or may have different shapes and dimensions. The pitch in the X axis direction of the mask openings 71 may be constant or different.

It is preferable that vapor deposition mask 70 is held by a mask tension mechanism (not shown). The mask tension mechanism prevents the occurrence of bending or extension of the vapor deposition mask 70 due to its own weight, by applying tension to the vapor deposition mask 70 in a direction parallel to the major surface thereof.

The limiting plate unit 80 is disposed between the vapor deposition source openings 61 and the vapor deposition mask 70. The limiting plate unit 80 includes a plurality of limiting plates 81 arranged at a constant pitch along the X axis direction. The space between the limiting plates 81 neighboring in the X axis direction is a limiting space 82 through which the vapor deposition particles 91 pass.

In the present embodiment, one vapor deposition source opening 61 is disposed at the center of limiting plates 81 neighboring in the X axis direction. Accordingly, one vapor deposition source opening 61 corresponds to one limiting space 82. However, the present invention is not limited to this, and the plurality of limiting spaces 82 may be configured to correspond to one vapor deposition source opening 61, or one limiting space 82 may be configured to correspond to the plurality of vapor deposition source openings 61. In the present invention, “the limiting space 82 corresponding to the vapor deposition source opening 61” refers to the limiting space 82 that is designed to allow the passage of the vapor deposition particles 91 discharged from the vapor deposition source opening 61.

In FIGS. 10 and 11, although the number of vapor deposition source openings 61 and the number of limiting spaces 82 are eight, the present invention is not limited to this and the number may be larger or smaller than this.

In the present embodiment, the limiting plate unit 80 is formed into a substantially rectangular parallelepiped object (or thick plate-like object) by forming through holes penetrating in the Z axis direction at a constant pitch in the X axis direction. Each through hole serves as the limiting space 82, and each wall between neighboring through holes serves as the limiting plate 81. However, the method for manufacturing the limiting plate unit 80 is not limited thereto. For example, the plurality of limiting plates 81 having the same dimension may be made separately and fixed to a holding body at a constant pitch by means of welding or the like.

A cooling device for cooling the limiting plates 81, or a temperature adjustment device for maintaining the limiting plates 81 at a fixed temperature may be provided on the limiting plate unit 80.

The vapor deposition source opening 61 and the plurality of limiting plates 81 are spaced apart from each other in the Z axis direction, and the plurality of limiting plates 81 and the vapor deposition mask 70 are spaced apart from each other in the Z axis direction. It is preferably that the relative position between the vapor deposition source 60, the limiting plate unit 80, and the vapor deposition mask 70 is substantially constant at least during vapor deposition by color.

The substrate 10 is held by a holding device 55. As the holding device 55, for example, an electrostatic chuck that holds the surface of the substrate 10 opposite to the deposition surface 10e of the substrate 10 with electrostatic force can be used. The substrate 10 can thereby be held substantially without the substrate 10 being bent by its own weight. However, the holding device 55 for holding the substrate 10 is not limited to an electrostatic chuck and may be any other device.

The substrate 10 held by the holding device 55 is scanned (moved) in the Y axis direction at a constant speed by a moving mechanism 56 with respect to the vapor deposition mask 70 on the opposite side from the vapor deposition source 60, with the substrate 10 being spaced apart from the vapor deposition mask 70 at a fixed interval.

The vapor deposition unit 50, the substrate 10, the holding device 55 for holding the substrate 10 and the moving mechanism 56 for moving the substrate 10 are housed in a vacuum chamber (not shown). The vacuum chamber is a hermetically sealed container, with its internal space being vacuumed and maintained to a predetermined low pressure state.

The vapor deposition particles 91 discharged from the vapor deposition source openings 61 pass through a limiting space 82 of the limiting plate unit 80, and a mask opening 71 of the vapor deposition mask 70 in this order. The deposition particles 91 adhere to the deposition surface (specifically, the surface of the substrate 10 opposing the vapor deposition mask 70) 10e of the substrate 10 traveling in the Y axis direction to form a coating film 90. The coating film 90 has a stripe shape extending in the Y axis direction.

The vapor deposition particles 91 that form the coating film 90 necessarily pass through the limiting space 82 and the mask opening 71. The limiting plate unit 80 and the vapor deposition mask 70 are designed so as to prevent a situation in which the vapor deposition particles 91 discharged from a vapor deposition source opening 61 reach the deposition surface 10e of the substrate 10 without passing through the limiting spaces 82 and the mask openings 71, and if necessary, a shielding plate (not shown) or the like that prevents flight of the vapor deposition particles 91 may be installed.

By performing vapor deposition three times by changing the vapor deposition material 91 for each color, namely, red, green and blue (vapor deposition by color), stripe-shaped coating films 90 (specifically, light emitting layers 23R, 23G and 23B) that correspond to the respective colors of red, green and blue can be formed on the deposition surface 10e of the substrate 10.

As with the limiting plates 981 of the new vapor deposition method shown in FIGS. 5 and 6, the limiting plates 81 limit the incidence angle of the vapor deposition particles 91 entering the mask openings 71 on a projection onto the XZ plane by causing the vapor deposition particles 91 having a large speed vector component in the X axis direction to collide with and adhere to the limiting plates 81. As used herein, “incidence angle” of the vapor deposition particles 91 with respect to a mask opening 71 is defined as the angle formed between the flight direction of the vapor deposition particles 91 entering the mask opening 71 and the Z axis on a projection onto the XZ plane. As a result, the amount of the vapor deposition particles 91 that pass through a mask opening 71 at a large incidence angle is reduced. Accordingly, the width We of the blur portion 90e shown in FIG. 8 is reduced, and thus the occurrence of blur at both edges of the stripe-shaped coating film 90 can be suppressed significantly.

In order to limit the incidence angle at the vapor deposition particles 91 enter the mask opening 71, the limiting plates 81 are used in the present embodiment. The dimension in the X axis direction of a limiting space 82 can be large, and the dimension in the Y axis direction can be set to substantially any value. Accordingly, the opening area of the limiting space 82 viewed from the vapor deposition source openings 61 is increased, and thus the amount of vapor deposition particles that adhere to the limiting plate unit 80 can be reduced, as a result of which the wasted vapor deposition material can be reduced. Also, clogging caused as a result of the vapor deposition material adhering to the limiting plates 81 is unlikely to occur, enabling continuous use for a long period of time and improving the mass productivity of the organic EL display device. Furthermore, because the opening area of the limiting plate 82 is large, the vapor deposition material that has adhered to the limiting plates 81 can be easily washed off, enabling simple maintenance and reducing the losses resulting from a stop of mass production, as a result of which the mass productivity can be further improved.

In the present embodiment, as shown in FIG. 11, side surfaces (hereinafter also referred to simply as “limiting plate side surfaces”) 83 of the limiting plates 81 that define limiting spaces 82 in the X axis direction are inclined such that the dimension in the X axis direction (or in other words, the interval between each pair of limiting plates 81 opposing in the X axis direction) of the limiting space 82 becomes smaller as the distance to the vapor deposition mask 70 decreases. That is, a narrowest portion 81n having the narrowest dimension in the X axis direction of the limiting space 82 is at the upper (on the vapor deposition mask 70 side) edges of the side surfaces 83, and the dimension in the X axis direction of the limiting space 82 becomes wider as the distance from the narrowest portion 81n to the vapor deposition source 60 increases. A pair of side surfaces 83 opposing in the X axis direction across the limiting space 82 are in plane symmetry relationship.

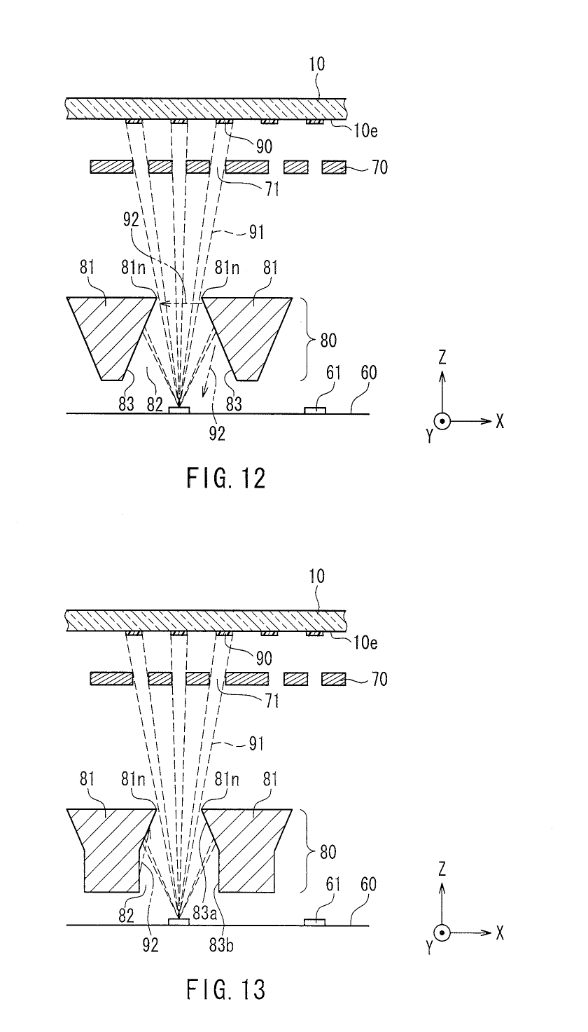

FIG. 12 is an enlarged cross-sectional view of the vapor deposition device of Embodiment 1. The function of the side surfaces 83 of the limiting plates 81 will be described with reference to FIG. 12.

As described with reference to FIG. 9B, in the present embodiment as well, the limiting plate unit 980 receives radiant heat from the vapor deposition source 960 maintained at a high temperature and thus is heated. Accordingly, the vapor deposition material that has adhered to the side surfaces 83 may be re-vaporized as vapor deposition particles. The double-dot-dashed lines shown in FIG. 12 illustratively indicate the flight trajectories of re-vaporized vapor deposition particles 92. The arrows at the tip end of the double-dot-dashed lines indicate the flight directions of the vapor deposition particles 92. The vapor deposition particles 92 re-vaporized off the side surfaces 83 fly in various directions, but generally have a distribution in which the amount of vapor deposition particles flying in the normal line direction of the side surfaces 83 is the largest. In the present embodiment, the side surfaces 83 are inclined as shown in FIG. 12, and thus the normal line direction of the side surfaces 83 points toward the vapor deposition source 60, and not toward the substrate 10. Accordingly, the number of vapor deposition particles traveling toward the substrate 10 among the re-vaporized vapor deposition particles is much smaller than that in FIG. 9B in which the side surfaces 983 are substantially parallel to the Z axis direction. Thus, the number of vapor deposition particles that pass through the mask openings 71 and adhere to the deposition surface 10e of the substrate 10 is further reduced. As a result, it is possible to solve the problems encountered with Patent Document 4 and the new vapor deposition method, which was described with reference to FIG. 9B, such as the vapor deposition material adhering to an undesired position on the substrate and causing a blur at the edge of the coating film, or causing an offset in the formation position of the coating film.

As described above, according to Embodiment 1, a coating film 90 in which the edge blur is suppressed can be formed at a desired position on the substrate 10 by performing pattern vapor deposition with high accuracy. As a result, in the organic EL display device, the need to increase the width of the non-light-emitting region between light-emitting regions so as to not cause color mixing is eliminated. Accordingly, it is possible to achieve display of high definition and high brightness images. In addition, the need to increase the current density in the light emitting layers in order to enhance brightness is also eliminated, and thus a long service life can be achieved and reliability can be improved.

Furthermore, the need to frequently replace the limiting plate unit 80 in order to reduce re-vaporization of vapor deposition material from the limiting plates 81 can be eliminated. Accordingly, the frequency of maintenance is reduced, throughput at the time of mass production is improved, and productivity is improved. Therefore, vapor deposition cost is reduced, and thus an inexpensive organic EL display device can be provided.

In Embodiment 1, there is no particular limitation on the angle of inclination of the side surfaces 83 with respect to the Z axis direction. The angle of inclination of the side surfaces 83 with respect to the Z axis direction is preferably large because the number of vapor deposition particles traveling toward the substrate 10 among the vapor deposition particles re-vaporized off the side surfaces 83 is reduced as the angle of inclination is increased (or in other words, as the normal line direction of the side surfaces 83 points more toward the vapor deposition source 60).

In the example described above, each of the side surfaces 83 of the limiting plates 81 is a single inclined surface, but the present invention is not limited to this configuration. For example, as shown in FIG. 13, it is also possible to provide first surfaces 83a inclined similarly to the side surfaces 83 shown in FIG. 12 on the vapor deposition mask 70 side in the Z axis direction, and provide second surfaces 83b that are substantially parallel to the Z axis direction on the vapor deposition source 60 side in the Z axis direction. In this case, the upper ends of the first surfaces 83a form the narrowest portion 81n. The first surfaces 83a are inclined similarly to the side surfaces 83 shown in FIG. 12, and thus the number of vapor deposition particles re-vaporized off the first surfaces 83a toward the substrate 10 is very small. On the other hand, as with the vapor deposition particles 92 re-vaporized off the side surfaces 983 shown in FIG. 9B, the vapor deposition particles 92 that fly toward the substrate 10 may be re-vaporized off the second surfaces 83b, but it is highly likely that such vapor deposition particles 92 will collide with and be captured by the first surfaces 83a that are disposed closer to the substrate 10 than the second surfaces 83b are. Accordingly, as in the case of FIG. 12, a coating film 90 in which the edge blur is suppressed can be formed at a desired position on the substrate 10. Also, the frequency of replacement of the limiting plate unit 80 can be reduced, and thus throughput at the time of mass production can be improved and productivity can be improved.

In FIG. 13, the second surfaces 83b do not need to be surfaces that are parallel to the Z axis, and may be inclined surfaces whose normal line points toward the substrate 10 or the vapor deposition source 60. The side surface of each limiting plate 81 may be configured with more surfaces.

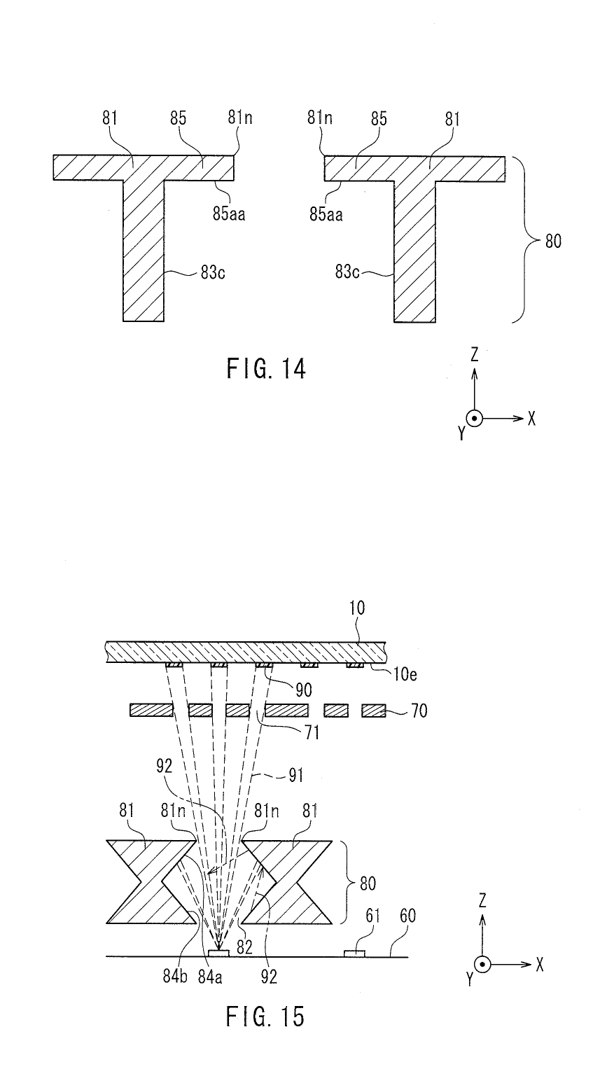

Furthermore, as shown in FIG. 14, an overhang (or brim or flange) 85 projecting toward the limiting space 82 may be formed at an edge of the side surface of each limiting plate 81, the edge being on the vapor deposition mask 70 side. In this case, the tip ends of the overhangs 85 form the narrowest portion 81n. The normal line direction of an undersurface (the surface opposing the vapor deposition source 60) 85aa of the overhang 85 is substantially parallel to the Z axis, and thus there are almost no vapor deposition particles re-vaporized off the undersurface 85aa toward the substrate 10. On the other hand, the vapor deposition particles re-vaporized off a surface 83c located below the overhang 85 (on the vapor deposition source 60 side) toward the substrate 10 will collide with and be captured by the undersurface 85aa of the overhang 85. Accordingly, with the configuration of FIG. 14, a coating film 90 in which the edge blur is further suppressed as compared with FIGS. 12 and 13 can be formed at a desired position on the substrate 10. Also, the frequency of replacement of the limiting plate unit 80 can be further reduced, and thus throughput at the time of mass production can be improved and productivity can be improved.

In FIG. 14, the surface 83c is a flat surface that is substantially parallel to the Z axis direction, but the configuration is not limited thereto, and the surface 83c may be a flat surface inclined with respect to the Z axis direction or may have any shape such as a curved surface. Also, in FIG. 14, the overhangs 85 are thin plates having a substantially constant thickness, but the configuration is not limited thereto, and the overhangs 85 may have, for example, a substantially wedge-shaped cross section that becomes thinner toward the tip end thereof.

### Embodiment 2

FIG. 15 is an enlarged cross-sectional view of a vapor deposition device according to Embodiment 2 of the present invention, as viewed in a direction parallel to the movement direction of the substrate 10. In FIG. 15, members that are the same as those shown in FIGS. 10 to 12 showing the vapor deposition device of Embodiment 1 are given the same reference numerals, and descriptions thereof are omitted here. Hereinafter, Embodiment 2 will be described, focusing on the difference from Embodiment 1.

Embodiment 2 is different from Embodiment 1 in the cross-sectional shape along the XZ plane of the limiting plates 81 of the limiting plate unit 80.

Specifically, as shown in FIG. 15, the side surfaces of the limiting plates 81 that define a limiting space 82 in the X axis direction each have two ends in the vertical direction (Z axis direction) protruding toward the limiting space 82, and a region between the two ends is recessed. In FIG. 15, the side surfaces of the limiting plates 81 each have, on the vapor deposition mask 70 side in the Z axis direction, a first surface 84a that is inclined similarly to the side surface 83 shown in FIG. 12, and have, on the vapor deposition source 60 side in the Z axis direction, a second surface 84b that is inclined in a direction opposite to the inclination of the first surface 84a. The normal line direction of the first surface 84a points toward the vapor deposition source 60, and the normal line direction of the second surface 84b points toward the substrate 10. The upper ends of the first surfaces 84a form the narrowest portion 81n. The double-dot-dashed lines shown in FIG. 12 illustratively indicate the flight trajectories of re-vaporized vapor deposition particles 92. The arrows at the tip end of the double-dot-dashed lines indicate the flight directions of the vapor deposition particles 92.

According to Embodiment 2, even if the vapor deposition material that has adhered to the first surface 84a is re-vaporized, the first surface 84a is inclined in the same direction as the side surface 83 of Embodiment 1 shown in FIG. 12, and thus as in the case described with reference to FIG. 12, the number of vapor deposition particles traveling toward the substrate 10 among the re-vaporized vapor deposition particles 92 is very small.

In addition, according to Embodiment 2, as compared with the side surface 83 (see FIG. 12) or the first surface 83a (see FIG. 13) of Embodiment 1, the first surface 84a can be inclined more steeply so as to oppose the vapor deposition source 60, without increasing the dimension in the Z axis direction of the limiting plates 81. Accordingly, the number of vapor deposition particles 92 re-vaporized off the first surface 84a toward the substrate 10 can be further reduced as compared with Embodiment 1.

On the other hand, the second surface 84b is inclined so as to oppose the vapor deposition mask 70, and thus usually the vapor deposition particles 91 are less likely to adhere to the second surface 84b, as compared with the second surface 83b shown in FIG. 13. Accordingly, the amount of vapor deposition material re-vaporized off the second surface 84b is relatively smaller than that in Embodiment 1. However, the vapor deposition particles 91 discharged from a vapor deposition source opening 61 located far away from the second surface 84b may adhere to the second surface 84b, depending on the inclination of the second surface 84b or the relative position of the second surface 84b with respect to the vapor deposition source opening 61. In this case, even if the vapor deposition material that has adhered to the second surface 84b is re-vaporized, it is highly likely that the re-vaporized vapor deposition particles 92 will collide with and be captured by the first surface 84a that is disposed closer to the substrate 10 than the second surface 84b is, as with the vapor deposition particles 92 re-vaporized off the second surface 83b shown in FIG. 13.

Therefore, according to Embodiment 2, a coating film 90 in which the edge blur is further suppressed as compared with Embodiment 1 can be formed at a desired position on the substrate 10. Also, the frequency of replacement of the limiting plate unit 80 can be further reduced, and thus throughput at the time of mass production can be improved and productivity can be improved.

Furthermore, according to Embodiment 2, the second surface 84b is formed below (on the vapor deposition source 60 side) the first surface 84a, and thus even if a large amount of vapor deposition material that has adhered to the first surface 84a separates and falls from the first surface 84a, the vapor deposition material will fall onto and be captured by the second surface 84b. As a result, the possibility that the vapor deposition material will fall onto the vapor deposition source 60 can be reduced. If the vapor deposition material separated from the limiting plates 81 falls onto the vapor deposition source 60 and is re-vaporized, the vapor deposition particles will adhere to an undesired position on the substrate 10. Also, if the vapor deposition material separated from the limiting plates 81 falls onto the vapor deposition source openings 61, the vapor deposition source openings 61 will be clogged. As a result, the coating film will not be formed at a desired position on the substrate 10. According to Embodiment 2, the possibility of the occurrence of such a disadvantage can be reduced.

In the above example, the side surface of each limiting plate 81 is constituted by a first surface 84a and a second surface 84b that are inclined in opposite directions to each other, but the present invention is not limited to this configuration.

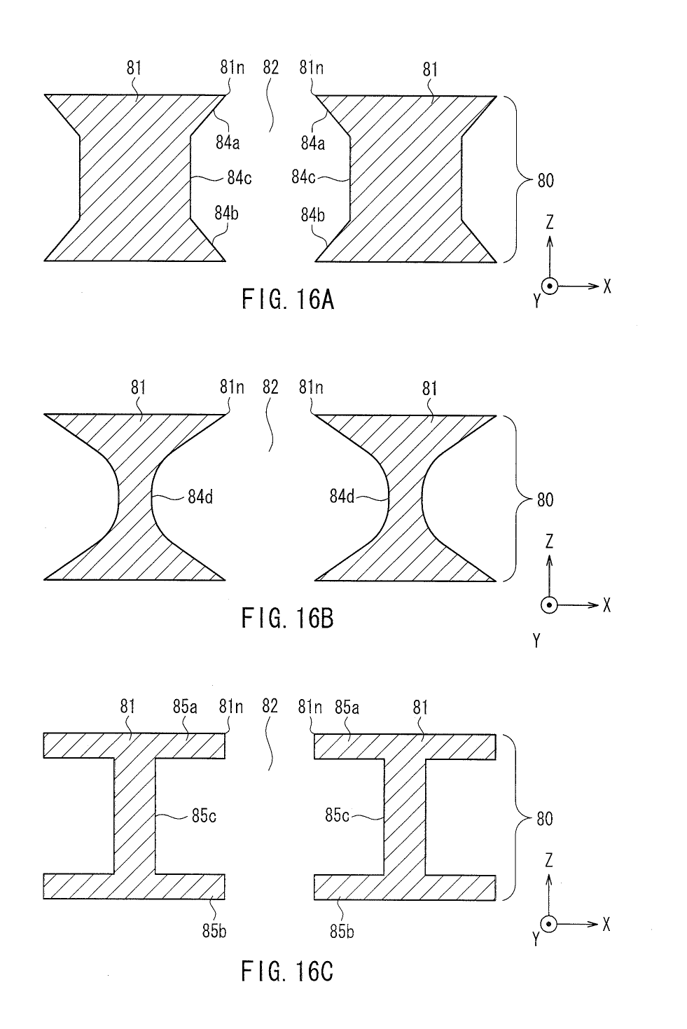

For example, as shown in FIG. 16A, a third surface 84c that is substantially parallel to the Z axis direction may be provided between the first surface 84a and the second surface 84b that are inclined similarly to the first surface 84a and the second surface 84b shown in FIG. 15. Although illustration is omitted, two or more surfaces that are inclined in different directions may be provided between the first surface 84a and the second surface 84b.

Alternatively, as shown in FIG. 16B, the side surfaces of the limiting plates 81 each may be a concavely curved surface 84d. The curved surface 84d can be, for example, a part of a cylindrical surface or any concavely curved surface. Each of the side surfaces of the limiting plates 81 does not need to be a single curved surface 84d as shown in FIG. 16B, and may be, for example, a combination of a plurality of curved surfaces whose curvature changes discontinuously or a combination of a curved surface and a flat surface.

Alternatively, as shown in FIG. 16C, overhangs (or brims or flanges) 85a and 85b protruding toward the limiting space 82 may be formed at two edges in the vertical direction (Z axis direction) of the side surface of each limiting plate 81. The tip ends of the first overhangs 85a located on the upper side (on the vapor deposition mask 70 side) form the narrowest portion 81n. As with the overhang 85 shown in FIG. 14, the first overhang 85a captures the vapor deposition particles re-vaporized off a region below the first overhang 85a of the limiting plate 81 toward the substrate 10. On the other hand, the second overhang 85b located on the lower side (on the vapor deposition source 60 side) prevents the vapor deposition particles from adhering to a connecting surface 85c between the first overhang 85a and the second overhang 85b. The upper surface of the second overhang 85b is substantially parallel to the XY plane. This is effective particularly to, even if the vapor deposition material accumulated on the undersurface of the first overhang 85a and the connecting surface 85c separates therefrom, receive the vapor deposition material and prevent the vapor deposition material from falling on the vapor deposition source 60 side. In FIG. 16C, the connecting surface 85c is a flat surface that is substantially parallel to the Z axis direction, but the present invention is not limited to this configuration. For example, the connecting surface 85c may be a flat surface whose normal line is inclined toward the substrate 10 or the vapor deposition source 60. Alternatively, the connecting surface 85c may be, instead of the flat surface 85c, an arbitrary curved surface (preferably a concavely curved surface).

### Embodiment 3

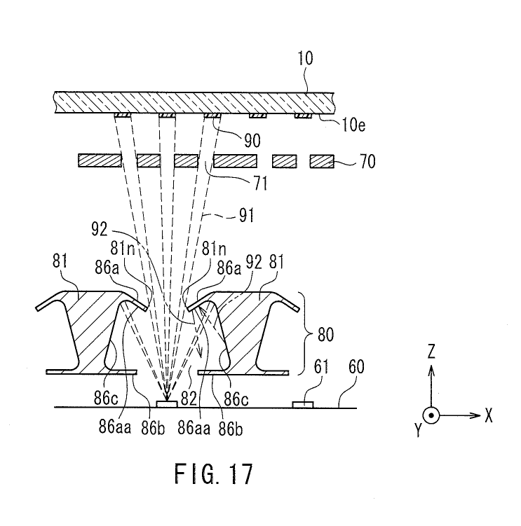

FIG. 17 is an enlarged cross-sectional view of a vapor deposition device according to Embodiment 3 of the present invention, as viewed in a direction parallel to the movement direction of the substrate 10. In FIG. 17, members that are the same as those shown in FIGS. 10 to 12 showing the vapor deposition device of Embodiment 1 are given the same reference numerals, and descriptions thereof are omitted here. Hereinafter, Embodiment 3 will be described, focusing on the difference from Embodiments 1 and 2.

Embodiment 3 is different from Embodiments 1 and 2 in the cross-sectional shape along the XZ plane of the limiting plates 81 of the limiting plate unit 80.

Specifically, as shown in FIG. 17, overhangs (or brims or flanges) 86a and 86b protruding toward the limiting space 82 are formed at two edges in the vertical direction (Z axis direction) of the side surface of each limiting plate 81 defining the limiting space 82 in the X axis direction. The tip ends of the first overhangs 86a located on the upper side (on the vapor deposition mask 70 side) form the narrowest portion 81n. Unlike the overhang 85 shown in FIG. 14 and the first overhang 85a shown in FIG. 16C, the first overhang 86a is inclined such that the first overhang 86a is closer to the vapor deposition source 60 as the distance to the tip end (the narrowest portion 81n) decreases. The first overhang 86a is a thin plate having a substantially uniform thickness, and therefore the undersurface (the surface opposing the vapor deposition source 60) 86aa of the first overhang 86a is also inclined similarly to the first overhang 86a. That is, the normal line direction of the undersurface 86aa of the first overhang 86a points to the limiting plate 81 itself (more specifically, the connecting surface 86c between the first overhang 86a and the second overhang 86b). Accordingly, there are substantially no vapor deposition particles that are re-vaporized off the undersurface 86aa of the first overhang 86a, pass through a space between the first overhangs 86a of neighboring limiting plates 81 and travel toward the substrate 10.

Also, the connecting surface 86c between the first overhang 86a and the second overhang 86b is inclined such that the dimension in the X axis direction of the limiting space 82 becomes larger as the distance to the vapor deposition source 60 decreases, as with the side surface 83 shown in FIG. 12. Accordingly, the number of vapor deposition particles traveling toward the substrate 10 among the vapor deposition particles re-vaporized off the connecting surface 86c is very small. Even if vapor deposition particles 92 are re-vaporized off the connecting surface 86c toward the substrate 10, the vapor deposition particles 92 will collide with and be captured by the undersurface 86aa of the first overhang 86a.

Accordingly, a coating film 90 in which the edge blur is further suppressed as compared with FIG. 16C can be formed at a desired position on the substrate 10. Also, the frequency of replacement of the limiting plate unit 80 can be further reduced, and thus throughput at the time of mass production can be improved and productivity can be improved.

As with the second overhang 85b shown in FIG. 16C, the second overhang 86b on the lower side (on the vapor deposition source 60 side) prevents vapor deposition particles from adhering to the connecting surface 86c, as well as receiving the vapor deposition material separated from the undersurface 86aa of the first overhang 86a and the connecting surface 85c and preventing the vapor deposition material from falling onto the vapor deposition source 60.

### Embodiment 4

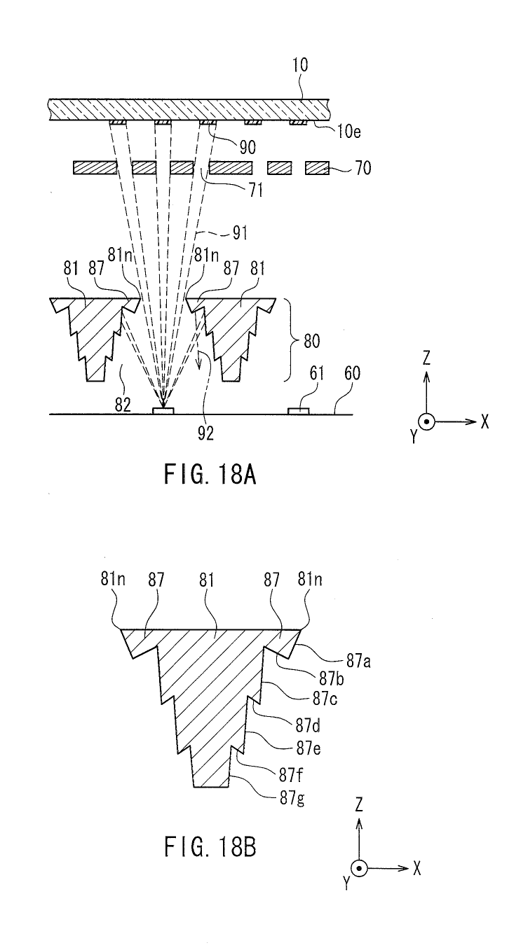

FIG. 18A is an enlarged cross-sectional view of a vapor deposition device according to Embodiment 4 of the present invention, as viewed in a direction parallel to the movement direction of the substrate 10. FIG. 18B is an enlarged cross-sectional view of a limiting plate 81 shown in FIG. 18A. In FIGS. 18A and 18B, members that are the same as those shown in FIGS. 10 to 12 showing the vapor deposition device of Embodiment 1 are given the same reference numerals, and descriptions thereof are omitted here. Hereinafter, Embodiment 4 will be described, focusing on the difference from Embodiments 1 to 3.

Embodiment 4 is different from Embodiments 1 to 3 in the cross-sectional shape along the XZ plane of the limiting plates 81 of the limiting plate unit 80.

Specifically, as shown in FIGS. 18A and 18B, the side surface of each limiting plate 81 defining the limiting space 82 in the X axis direction has a plurality of steps in a substantially stepwise arrangement (substantially saw-like arrangement). The steps are formed by surfaces 87a, 87b, 87c, 87d, 87e, 87f and 87g that are disposed in order from the vapor deposition mask 70 toward the vapor deposition source 60. An overhang (or brim or flange) 87 protruding toward the limiting space 82 is formed at an upper edge of the limiting plate 81. The surface 87a constitutes a distal surface of the overhang 87. The narrowest portion 81n is located at an upper end of the surface 87a.

The positions in the X axis direction of surfaces 87a, 87c, 87e and 87g are successively shifted so that the dimension in the X axis direction of the limiting space 82 is increased as the distance to the vapor deposition source 60 decreases. The surfaces 87a, 87c, 87e and 87g are successively connected by surfaces 87b, 87d and 87f. Accordingly, as viewed macroscopically, the side surface of the limiting plate 81 having a plurality of steps in a substantially stepwise arrangement is inclined such that the dimension in the X axis direction of the limiting space 82 becomes larger as the distance to the vapor deposition source 60 decreases.

The surfaces 87a, 87c, 87e and 87g are inclined such that the dimension in the X axis direction of the limiting space 82 is increased as the distance to the vapor deposition source 60 decreases, as with the side surface 83 shown in FIG. 12. Accordingly, the number of vapor deposition particles traveling toward the substrate 10 among the vapor deposition particles re-vaporized off the surfaces 87a, 87c, 87e and 87g is very small. Even if vapor deposition particles are re-vaporized off the surfaces 87c, 87e and 87g toward the substrate 10, the vapor deposition particles will collide with and be captured by the surfaces 87b, 87d and 87f.

Also, the surfaces 87b, 87d and 87f are inclined in the same direction as the undersurface 86aa of the first overhang 86a shown in FIG. 17, and thus there are substantially no vapor deposition particles that are re-vaporized off the surfaces 87b, 87d and 87f, pass through a space between the overhangs 87 of neighboring limiting plates 81 and travel toward the substrate 10.

Therefore, according to the present embodiment, a coating film 90 in which the edge blur is further suppressed can be formed at a desired position on the substrate 10. Also, the frequency of replacement of the limiting plate unit 80 can be further reduced, and thus throughput at the time of mass production can be improved and productivity can be improved.

The direction of inclination of the surfaces 87b, 87d and 87f is not limited to that described above. For example, the surfaces 87b, 87d and 87f may be surfaces whose normal line direction is parallel to the Z axis.

The direction of inclination of the surfaces 87a, 87c, 87e and 87g is not limited to that described above, either. For example, the surfaces 87a, 87c, 87e and 87g may be surfaces parallel to the Z axis direction. However, in order to reduce the number of vapor deposition particles re-vaporized off the surface 87a toward the substrate 10, the distal surface 87a of the overhang 87 is preferably inclined in the direction shown in FIGS. 18A and 18B.

The number of inclined surfaces that form the steps in a substantially stepwise arrangement of the side surface of the limiting plate 81 can be any number, and may be either greater or less than that shown in FIGS. 18A and 18B.

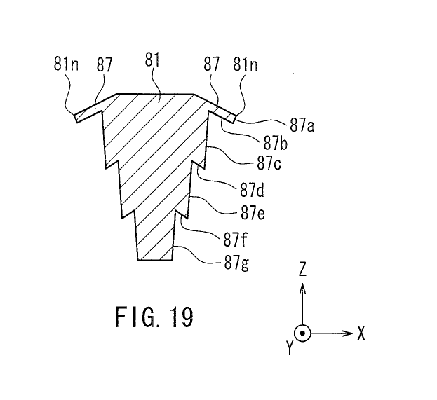

As shown in FIG. 19, the overhang 87 may be formed by using a thin plate so that the upper surface of the overhang 87 is parallel to the surface 87b. This configuration can reduce the area of the distal surface 87a of the overhang 87, as a result of which the vapor deposition particles re-vaporized off the surface 87a can be reduced. Accordingly, the number of vapor deposition particles re-vaporized toward the substrate 10 can be reduced as well. Alternatively, in order to further reduce the area of the distal surface 87a of the overhang 87, the cross-sectional shape of the overhang 87 may be formed in a substantially wedge shape that becomes thinner toward the distal surface 87a.

In Embodiment 4, a second overhang similar to the second overhang 85b shown in FIG. 16C or the second overhang 86b shown in FIG. 17 may be formed at the lower edges of the side surface of the limiting plate 81. In this case, the same effects as those of the second overhangs 85b and 86b can be obtained.

Embodiments 1 to 4 described above are merely illustrative. The present invention is not limited to Embodiments 1 to 4 described above and can be modified as appropriate.

Embodiments 1 to 4 given above described the side surfaces of the limiting plates 81 defining the limiting spaces 82 in the X axis direction, but in addition to this, the side surfaces 89 (see FIG. 10) of the limiting plate unit 80 that define the limiting spaces 82 in the Y axis direction may have the same configuration as the side surfaces of the limiting plates 81 described in Embodiments 1 to 4 given above. There is a possibility that the vapor deposition material that has adhered to the side surfaces 89 will also be re-vaporized. In this case, it is difficult to control the flight directions (the components thereof in the X axis direction in particular) of the re-vaporized vapor deposition particles. Accordingly, by configuring the side surfaces 89 in the same manner as the side surfaces of the limiting plates 81, it is possible to suppress a situation in which the vapor deposition material adheres to an undesired position on the substrate due to the vapor deposition particles re-vaporized off the side surfaces 89.

In Embodiments 1 to 4 described above, the vapor deposition source 60 has a plurality of the nozzle-shaped vapor deposition source openings 61 arranged at equal pitch in the X axis direction, but the shapes of the vapor deposition source openings are not limited to this in the present invention. For example, the vapor deposition source openings may have a slot shape extending in the X axis direction. In this case, a single slot-shaped vapor deposition source opening may be disposed so as to correspond to a plurality of the limiting spaces 82.

If the substrate 10 has a large dimension in the X axis direction, a plurality of vapor deposition units 50 as shown in the above-described embodiments may be arranged at different positions in the X axis direction and in the Y axis direction.

In Embodiments 1 to 4 described above, the substrate 10 is moved relative to the vapor deposition unit 50 that is stationary, but the present invention is not limited thereto. It is sufficient that one of the vapor deposition unit 50 and the substrate 10 is moved relative to the other. For example, it may be possible to fix the position of the substrate 10 and move the vapor deposition unit 50. Alternatively, both the vapor deposition unit 50 and the substrate 10 may be moved.

In Embodiments 1 to 4 described above, the substrate 10 is disposed above the vapor deposition unit 50, but the relative positional relationship between the vapor deposition unit 50 and the substrate 10 is not limited thereto. It may be possible to, for example, dispose the substrate 10 below the vapor deposition unit 50 or dispose the vapor deposition unit 50 and the substrate 10 so as to oppose each other in the horizontal direction.

### INDUSTRIAL APPLICABILITY

There is no particular limitation on the fields to which the vapor deposition device and vapor deposition method of the present invention can be applied, and the present invention is preferably used to form light emitting layers for use in organic EL display devices.

### DESCRIPTION OF SYMBOLS

10 Substrate
10e Deposition Surface
20 Organic EL Element
23R, 23G, 23B Light Emitting Layer
50 Vapor Deposition Unit
56 Moving Mechanism
60 Vapor Deposition Source
61 Vapor Deposition Source Opening
70 Vapor Deposition Mask
71 Mask Opening
80 Limiting Plate Unit
81 Limiting Plate
81n Narrowest Portion of Limiting Space
82 Limiting Space
83 Side Surface
83a,84a First Surface
83b,84b Second Surface
84c Third Surface
84d Curved Surface
83c Surface
85,87 Overhang
85a,86a First Overhang
85b,86b Second Overhang
85c,86c Connecting Surface
87a,87b,87c,87d,87e,87f,87g Surface
89 Side Surface of Limiting Plate Unit
91 Vapor Deposition Particles
92 Re-Vaporized Vapor Deposition Particles

1. A vapor deposition device that forms a coating film having a predetermined pattern on a substrate, the vapor deposition device comprising:
a vapor deposition unit including a vapor deposition source having at least one vapor deposition source opening, a vapor deposition mask disposed between the at least one vapor deposition source opening and the substrate, and a limiting plate unit that is disposed between the vapor deposition source and the vapor deposition mask and that includes a plurality of limiting plates disposed along a first direction; and
a moving mechanism that moves one of the substrate and the vapor deposition unit relative to the other along a second direction orthogonal to a normal line direction of the substrate and the first direction in a state in which the substrate and the vapor deposition mask are spaced apart at a fixed interval,
wherein the coating film is formed by causing vapor deposition particles that have been discharged from the at least one vapor deposition source opening and passed through a limiting space between the limiting plates neighboring in the first direction and a plurality of mask openings formed in the vapor deposition mask to adhere onto the substrate, and
side surfaces of the limiting plates that define the limiting space in the first direction are configured such that a portion having a dimension in the first direction of the limiting space wider than a narrowest portion having a narrowest dimension in the first direction of the limiting space is formed on at least the vapor deposition source side with respect to the narrowest portion.

2. The vapor deposition device according to claim 1,
wherein the side surfaces of the limiting plates opposing in the first direction across the limiting space are in plane symmetry relationship.

3. The vapor deposition device according to claim 1,
wherein the narrowest portion is provided at edges of the side surfaces of the limiting plates on the vapor deposition mask side.

4. The vapor deposition device according to claim 1,
wherein the side surface of each of the limiting plates has, on the vapor deposition source side with respect to the narrowest portion, a surface that is inclined such that the dimension in the first direction of the limiting space increases as the distance from the narrowest portion increases along the normal line direction of the substrate.

5. The vapor deposition device according to claim 1,
wherein a recess is formed in a region of the side surface of each of the limiting plates, the region being located on the vapor deposition source side with respect to the narrowest portion.

6. The vapor deposition device according to claim 1,
wherein a first overhang protruding toward the limiting space is formed on the side surface of each of the limiting plates, and
the narrowest portion is provided at tip ends of the first overhangs.

7. The vapor deposition device according to claim 6,
wherein the first overhang has, on the vapor deposition source side, a surface that is inclined such that the surface of the first overhang is closer to the vapor deposition source as the distance to the tip end decreases.

8. The vapor deposition device according to claim 6,
wherein the first overhang has, at the tip end thereof, a surface that is inclined such that the dimension in the first direction of the limiting space increases as the distance to the vapor deposition source decreases.

9. The vapor deposition device according to claim 1,
wherein a second overhang protruding toward the limiting space is formed on the side surface of each of the limiting plates at a position on the vapor deposition source side with respect to the narrowest portion.

10. The vapor deposition device according to claim 1,
wherein each of the side surfaces of the limiting plates has a plurality of steps in a stepwise arrangement.

11. The vapor deposition device according to claim 1,
wherein side surfaces of the limiting plate unit that define the limiting space in the second direction are configured such that a portion having a dimension in the second direction of the limiting space wider than a second narrowest portion having a narrowest dimension in the second direction of the limiting space is formed on at least the vapor deposition source side with respect to the second narrowest portion.

12. A vapor deposition method comprising a vapor deposition step of forming a coating film having a predetermined pattern on a substrate by causing vapor deposition particles to adhere onto the substrate,
wherein the vapor deposition step is performed by using the vapor deposition device according to claim 1.

13. The vapor deposition method according to claim 12,
wherein the coating film is a light emitting layer for an organic EL element.

14. An organic EL display device comprising a light emitting layer formed by using the vapor deposition method according to claim 12.
